(19) United States
(12) Patent Application Publication
(10) Pub. No.: US 2025/0098477 A1
(43) Pub. Date: Mar. 20, 2025

(54) LIGHT-EMITTING DEVICE AND METHOD FOR MANUFACTURING SAME

(71) Applicant: Sharp Display Tichnology Corporation, Kameyama City, Shiraki-cho (JP)

(72) Inventors: Youhei NAKANISHI, Kameyama City, Mie (JP); Takeshi ISHIDA, Kameyama City, Mie (JP); Alessandro MINOTTO, London, Greater London (GB); Peter Neil TAYLOR, Oxford, Oxfordshire (GB); Valerie BERRYMAN-BOUSQUET, Chipping Norton, Oxfordshire (GB)

(21) Appl. No.: 18/730,311

(22) PCT Filed: Mar. 24, 2022
(86) PCT No.: PCT/JP2022/013834

§ 371 Date: Jul. 19, 2024

(51) Int. Cl. H10K 59/00; B82Y 20/00; B82Y 40/00; H10K 50/115; H10K 59/12; H10K 59/35

(52) U.S. Cl. CPC H10K 59/771; H10K 59/1201; H10K 59/353; B82Y 20/00; B82Y 40/00; H10K 50/115

(57) ABSTRACT

A light-emitting device includes at least one light-emitting region. The at least one light-emitting region includes: a lower electrode in plan view; an upper electrode provided across from at least one lower electrode including the lower electrode; and a plurality of functional layers stacked on top of another between the lower electrode and the upper electrode. The plurality of functional layers include at least: a light-emitting layer provided between the lower electrode and the upper electrode; and a first functional layer provided between the lower electrode and the light-emitting layer, and adjacent to the light-emitting layer. The light-emitting layer contains quantum dots, ligands, and a photo-crosslinking agent. The first functional layer contains a photocurable resin. An end face of the light-emitting layer and an end face of the first functional layer are flush with each other.

### TECHNICAL FIELD

The present disclosure relates to a light-emitting device and a method for manufacturing the light-emitting device.

### BACKGROUND ART

Patent Document 1 discloses a method for manufacturing a light-emitting device using a technique to pattern a light-emitting layer; that is, the quantum-dot ligand crosslinker (QD-LiXer) technique.

The QD-LiXer technique involves providing a photo-crosslinkable property to a quantum-dot material contained in the light-emitting layer and patterning the light-emitting layer as if using a negative resist. In the QD-LiXer technique, a photo-crosslinking agent is added to quantum dots. Then, ligands on the surface of the quantum dots are exposed to light and crosslinked, and an uncrosslinked non-light-exposed portion of the quantum dots is dissolved with a developing solution and removed. Hence, the QD-LiXer technique can pattern the light-emitting layer with fewer steps than such a technique as the lift-off technique can. Furthermore, the QD-LiXer technique eliminates the need of a sacrificial layer such as a resist when patterning a light-emitting layer. In view of these points, the QD-LiXer technique is superior to known photolithography techniques such as the lift-off technique.

### CITATION LIST

### Patent Literature

[Patent Document 1] United States Patent Application Publication No. 2019/0312204

### SUMMARY

### Technical Problems

However, the QD-LiXer technique has a problem of difficulty in removing all the quantum dots in the non-light-exposed portion during the development.

The inventors of the present disclosure have conducted studies and found out that, when the QD-LiXer technique is used for patterning the light-emitting layer, the photo-crosslinking agent binds the quantum dots to a functional layer serving as an underlayer of the light-emitting layer, and a residue of the light-emitting layer might be left in a region where the light-emitting layer is supposed to be patterned and removed. Such a residue causes decreases in the performance and color purity of the light-emitting device.

An aspect of the present disclosure is devised in view of the above problems, and sets out to provide a light-emitting device having no residue of a light-emitting layer left in a region where the light-emitting layer is supposed to be patterned and removed, thereby presenting excellent performance and color purity. The aspect of the present disclosure also sets out to provide a method for manufacturing the light-emitting device.

### Solution to Problems

In order to solve the above problems, a light-emitting device according to an aspect of the present disclosure includes at least one light-emitting region. The at least one light-emitting region includes: a lower electrode in plan view; an upper electrode provided across from at least one lower electrode including the lower electrode; and a plurality of functional layers stacked on top of another between the lower electrode and the upper electrode. The plurality of functional layers include at least: a light-emitting layer provided between the lower electrode and the upper electrode; and a first functional layer provided between the lower electrode and the light-emitting layer, and adjacent to the light-emitting layer. The light-emitting layer contains quantum dots, ligands, and a photo-crosslinking agent. The first functional layer contains a photocurable resin. An end face of the light-emitting layer and an end face of the first functional layer are flush with each other.

In order to solve the above problems, a method for manufacturing a light-emitting device, including at least one light-emitting region, includes: a lower electrode forming step of forming, in plan view, a lower electrode in the at least one light-emitting region; a functional layer forming step of forming a plurality of functional layers above the lower electrode in the at least one light-emitting region; and an upper electrode forming step of forming an upper electrode, across from at least one lower electrode including the lower electrode, above the plurality of functional layers in the at least one light-emitting region. The functional layer forming step includes: a first-functional-film depositing step of depositing a first functional film containing a photocurable compound; a quantum-dot-containing-film depositing step of depositing a quantum-dot-containing film above, and adjacent to, the first functional film, the quantum-dot-containing film containing the quantum dots, ligands, and photo-crosslinking agent; a quantum-dot-containing-film exposing step of exposing a first region, which is a portion of the quantum-dot-containing film, with light to activate the photo-crosslinking agent, and crosslinking the photo-crosslinking agent and the ligands in the first region; a first-functional-film exposing step of exposing a second region, which is included in the first functional film and overlaps with the first region, with light to activate the photocurable compound, and curing the photocurable compound in the second region to form a photocurable resin; and a patterning step of developing to pattern the quantum-dot-containing film and the first functional film, so that the quantum-dot-containing film is patterned to form a light-emitting layer, and the first functional film is patterned to form a first functional layer having an end face flush with an end face of the light-emitting layer.

### Advantageous Effects of Disclosure

An aspect of the present disclosure can provide a light-emitting device having no residue of a light-emitting layer left in a region where the light-emitting layer is supposed to be patterned and removed, thereby presenting excellent performance and color purity. The aspect of the present disclosure can also provide a method for manufacturing the light-emitting device.

### BRIEF DESCRIPTION OF DRAWINGS

FIG. 1 is a cross-sectional view illustrating an example of a schematic configuration of a main feature of a display device according to a first embodiment.

FIG. 2 is a schematic view illustrating an example of a schematic configuration of a light-emitting layer included in the display device according to the first embodiment.

FIG. 3 shows cross-sectional views illustrating some steps of forming a light-emitting element layer of the display device illustrated in FIG. 1.

FIG. 4 shows cross-sectional views illustrating other steps of forming the light-emitting element layer of the display device illustrated in FIG. 1.

FIG. 5 shows cross-sectional views illustrating yet other steps of forming the light-emitting element layer of the display device illustrated in FIG. 1.

FIG. 6 shows cross-sectional views illustrating still yet other steps of forming the light-emitting element layer of the display device illustrated in FIG. 1.

FIG. 7 is a cross-sectional view illustrating an example of a schematic configuration of a main feature of a display device according to a second embodiment.

FIG. 8 is a cross-sectional view illustrating an example of a schematic configuration of a main feature of a display device according to a third embodiment.

FIG. 9 is a cross-sectional view illustrating an example of a schematic configuration of a main feature of a display device according to a fourth embodiment.

### DESCRIPTION OF EMBODIMENTS

Embodiments of the present disclosure will be described below. For convenience in description, like reference signs designate members having identical functions throughout the embodiments. These members will not be elaborated upon repeatedly. In a second and subsequent embodiments, differences from the previously described embodiments will be described. As a matter of course, unless otherwise described, the second and subsequent embodiments can be modified in the same manner as the previously described embodiments.

### First Embodiment

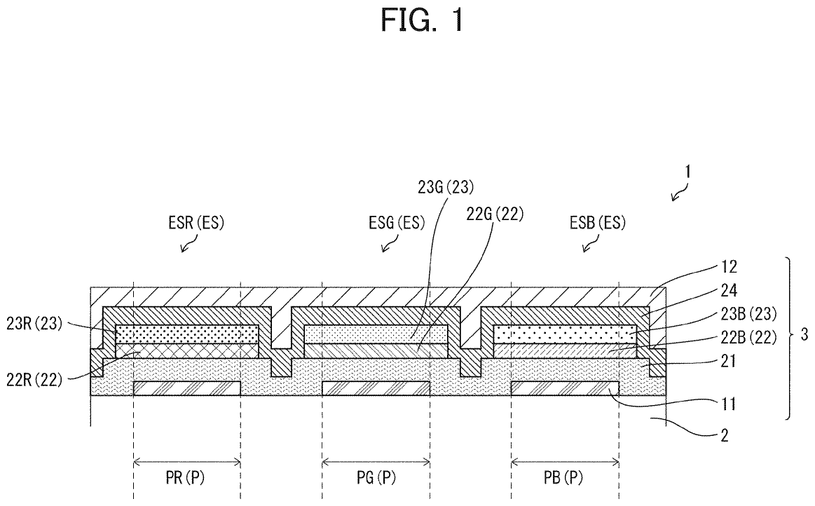

An embodiment of the present disclosure will be described below, with reference to FIGS. 1 to 6. This embodiment exemplifies a case where a light-emitting device according to this embodiment is a display device.

### Schematic Configuration of Display Device

FIG. 1 is a cross-sectional view illustrating an example of a schematic configuration of a main feature of a display device 1 (a light-emitting device) according to this embodiment.

The display device 1 has a plurality of pixels P (i.e., light-emitting regions). Each of the pixels P is provided with a light-emitting element ES. The display device 1 illustrated in FIG. 1 includes, as a substrate 2, an array substrate in which a drive element layer is formed. The display device 2 further includes a light-emitting element layer 3 provided on the substrate 2 and including a plurality of the light-emitting elements ES having different emission wavelengths. The light-emitting element layer 3 is covered with, for example, a not-shown sealing layer. Furthermore, on the sealing layer, a not-shown functional film may be provided as necessary. The functional film may have at least one of, for example, an adaptive optics correction function, a touch sensor function, or a protection function.

In this embodiment, the direction from the light-emitting elements ES toward the substrate 2 of the display device 1 is referred to as a “downward direction”, and the direction from the substrate 2 toward the light-emitting elements ES of the display device 1 is referred to as an “upward direction”. Furthermore, in this embodiment, the term “below” means that a constituent feature is formed in a previous process before a comparative layer, and the term “above” means that a constituent feature is formed in a successive process after a comparative layer.

The plurality of pixels P have different peak emission wavelengths. As an example, the pixels P of the display device 1 include, for example, a red pixel PR (a red light-emitting region) that emits a red (R) light, a green pixel PG (a green light-emitting region) that emits a green (G) light, and a blue pixel PB (a blue light-emitting region) that emits a blue (B) light.

The red pixel PR is provided with a red light-emitting element ESR serving as a light-emitting element ES whose light-emitting layer emits a red light. The green pixel PG is provided with a green light-emitting element ESG serving as a light-emitting element ES whose light-emitting layer emits a green light. The blue pixel PB is provided with a blue light-emitting element ESB serving as a light-emitting element ES whose light-emitting layer emits a blue light.

Note that, in the present disclosure, in a case where the red light-emitting element ESR, the green light-emitting element ESG, and the blue light-emitting element ESB do not have to be particularly distinguished from one another, the red light-emitting element ESR, the green light-emitting element ESG, and the blue light-emitting element ESB are collectively referred to as a “light-emitting element ES”. Similarly, in the present disclosure, in a case where the red pixel PR, the green pixel PG, and the blue pixel PB do not have to be particularly distinguished from one another, the red pixel PR, the green pixel PG, and the blue pixel PB are collectively referred to as a “pixel P”.

The substrate 2 functions as a support body for forming the layers of the light-emitting element ES. The substrate 2 includes, for example: an insulating substrate serving as a base substrate; and a TFT layer provided on the insulating substrate, serving as a drive element layer, and having a plurality of thin-film transistors (TFTs).

The display device 1 may be either a foldable flexible display device or a rigid (non-flexible) unfoldable display device. Hence, the insulating substrate may be, for example, a rigid inorganic substrate such as, for example, a glass substrate. Alternatively, the insulating substrate may be a flexible substrate mainly formed of such a resin as polyimide.

Furthermore, the insulating substrate has a surface provided with a barrier layer to prevent foreign substances such as water and oxygen from entering the TFT layer and the light-emitting element layer 3. Such a barrier layer can be, for example, a silicon oxide film, a silicon nitride film, or a silicon oxynitride film formed by chemical vapor deposition (CVD). Alternatively, the barrier layer can be a multilayer film including these films.

The TFT layer includes: pixel circuits that control the light-emitting elements ES; and a plurality of wires connecting to the pixel circuits. The pixel circuits are provided in a display region for the respective pixels P, so that each of the pixel circuits corresponds to one of the pixels P. The pixel circuit includes a plurality of TFTs. The plurality of TFTs are electrically connected to a plurality of wires including such wires as a gate wire and a source wire. These TFTs may have a known structure, and the structure shall not be limited to a particular structure.

The TFT layer has a surface provided with a planarization film covering the plurality of TFTs to planarize surfaces of the plurality of TFTs. The planarization film may be formed of, for example, an organic insulating material such as polyimide or acrylic resin.

The light-emitting element layer 3 includes the plurality of light-emitting elements ES provided for the respective pixels P. Above the substrate 2, the layers of each of the light-emitting elements ES are stacked on top of another.

The light-emitting element layer 3 includes: a plurality of lower electrodes provided on the planarization film in plan view, and each corresponding to one of the plurality of pixels P; an upper electrode provided across from the plurality of lower electrodes; and a plurality of functional layers stacked on top of another between each of the lower electrodes and the upper electrode.

Each of the lower electrodes, which functions as a pixel electrode, is shaped into an island and provided on the substrate 2 for a corresponding one of the light-emitting elements ES (i.e., a corresponding one of the pixels P). The upper electrode, which functions as a common electrode, is provided in common to all the light-emitting elements ES (i.e., all the pixels P). Hence, an anode 11 and a cathode 12 are provided across from each other for each of the pixels P. The light-emitting elements ES function as light sources to cause the respective pixels P to glow. Each of the lower electrodes is electrically connected to a corresponding one of the TFTs of the substrate 2.

In this embodiment, layers between the lower electrodes and the upper electrode are referred to as functional layers. The plurality of functional layers include at least: a light-emitting layer provided between each lower electrode and the upper electrode; and a first functional layer provided between the lower layer and the light-emitting layer, and adjacent to the light-emitting layer. Examples of the functional layers other than the light-emitting layer include a hole injection layer, a hole transport layer, an electron injection layer, an electron transport layer, an electron blocking layer, and a hole blocking layer.

Hereinafter, the light-emitting layer is referred to as an “EML”, the hole injection layer is referred to as an “HIL”, the hole transport layer is referred to as an “HTL”, the electron injection layer is referred to as an “EIL”, the electron transport layer is referred to as an “ETL”, the electron blocking layer is referred to as an “EBL”, and the hole blocking layer as an “HBL”.

Hereinafter, as illustrated in FIG. 1, described as an example will be a case where the lower electrode is the anode 11, the upper electrode is the cathode 12, and the first functional layer is the HTL 22. However, the display device 1 shall not be limited to such a case.

The red light-emitting element ESR illustrated in FIG. 1 includes: the anode 11, an HIL 21, an HTL 22R, an EML 23R, an ETL 24, and the cathode 12, all of which are stacked on top of another in the stated order from toward the substrate 2. Furthermore, the green light-emitting element ESG illustrated in FIG. 1 includes: the anode 11, the HIL 21, an HTL 22G, an EML 23G, the ETL 24, and the cathode 12, all of which are stacked on top of another in the stated order from toward the substrate 2. The blue light-emitting element ESB illustrated in FIG. 1 includes: the anode 11, the HIL 21, an HTL 22B, an EML 23B, the ETL 24, and the cathode 12, all of which are stacked on top of another in the stated order from toward the substrate 2.

Note that, in the present disclosure, in a case where the HTL 22R, the HTL 22G, and the HTL 22B do not have to be particularly distinguished from one another, the HTL 22R, the HTL 22G, and the HTL 22B are collectively referred to as an “HTL 22”. Similarly, in a case where the EML 23R, the EML 22G, and the EML 22B do not have to be particularly distinguished from one another, the EML 23R, the EML 22G, and the EML 22B are collectively referred to as an “EML 23”.

The anode 11 is an electrode that receives a voltage and supplies holes to the EML 23. The cathode 12 is an electrode that receives a voltage and supplies electrons to the EML 23. Each of the anode 11 and the cathode 12 contains a conductive material and connects to a not-shown power supply, so that a voltage is applied between the anode 11 and the cathode 12.

At least one of the anode 11 or the cathode 12 is a light-transparent electrode. Note that either the anode 11 or the cathode 12 may be reflective to light; that is, a reflective electrode. Each of the light-emitting elements ES can release light from toward a light-transparent electrode.

If the display device 1 is a top-emission display device that emits light from toward the upper electrode (i.e., if each of the light-emitting elements ES is a top-emission light-emitting element), the upper electrode is a light-transparent electrode, and the lower electrode is a reflective electrode. Whereas, if the display device 1 is a bottom-emission display device that emits light from toward the lower electrode (i.e., if each of the light-emitting elements ES is a bottom-emission light-emitting element), the lower electrode is a light-transparent electrode, and the upper electrode is a reflective electrode.

The light-transparent electrode is formed of a conductive light-transparent material such as, for example, indium tin oxide (ITO), indium zinc oxide (IZO), silver nanowire (AgNW), a thin-film of a magnesium-silver (MgAg) alloy, or a thin-film of silver (Ag).

Whereas, the reflective electrode is formed of a conductive light-reflective material including a metal such as, for example, silver (Ag), aluminum (Al), or copper (Cu), or including an alloy containing these metals. Note that a layer made of the light-transparent material and a layer made of the light-reflective material may be stacked on top of another to form the reflective electrode.

The lower electrode and the upper electrode are deposited by a typical technique to deposit an electrode; that is, for example, vapor deposition, sputtering, or inkjet printing. Note that, in forming the lower electrodes, a conductive material may be monolithically deposited over the entire pixel region (i.e., the display region) provided with the plurality of pixels P, and, after that, the conductive material may be patterned by, for example, photolithography or inkjet printing for each of pixels P to form the lower electrodes.

Among the functional layers, the EML 23 contains a light-emitting material, and emits light by recombination of the holes transported from the anode 11 and the electrons transported from the cathode 12. The light-emitting element ES according to this embodiment is a self-luminous element referred to as a nano-LED, a quantum-dot light-emitting diode (QLED), or a quantum-dot electroluminescence. The EML23 contains, as a light-emitting material, quantum dots (hereinafter referred to as “QDs”) 51 on a nanoscale based on a color of light to be emitted.

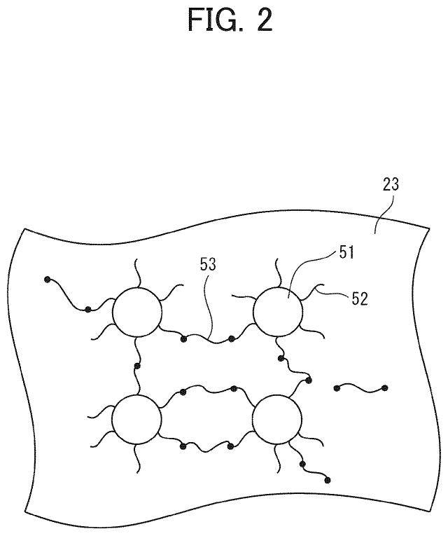

FIG. 2 is a schematic view illustrating an example of a schematic configuration of the EML 23 according to this embodiment. The EML 23 according to this embodiment contains: the QDs 51; ligands 52; and a photo-crosslinking agent 53.

Each of the QDs 51 is a dot made of an inorganic nanoparticle having a maximum width of 100 nm or less. The QD is also referred to as a semiconductor nanoparticle because a typical composition of the QD is derived from a semiconductor material. Moreover, the QD is also referred to as a nanocrystal because the QD has a specific crystal structure.

The QD 51 may have any given shape as long as the maximum width of the QD 51 is within the above range. The shape of the QD 51 shall not be limited to a three-dimensional spherical shape (a circular cross-section). For example, the QD 51 may have a polygonal cross-section, a bar-like three dimensional shape, a branch-like three dimensional shape, or a three dimensional shape having asperities on the surface. Alternatively, the QD 51 may have a combination of those shapes.

Each of the QDs 51 may be a core QD. Alternatively, each of the QDs 51 may be either a core-shell QD containing a core and a shell, or a core-multishell QD containing a core and shells. If the QD 51 contains a shell, the QD 51 may have a core in the center, and the shell may be provided to a surface of the core. The shell desirably covers the entire core; however, the shell does not have to completely cover the core. Furthermore, the QD 51 may be a binary-core QD, a tertiary-core QD, or a quaternary-core QD. Note that the QDs 51 may contain doped nanoparticles, or may have a composition-gradient structure.

The core may be formed of, for example, Si, Ge, CdSe, CdS, CdTe, InP, GaP, InN, ZnSe, ZnS, ZnTe, CdSeTe, GalnP, or ZnSeTe. The shell may be formed of, for example, CdS, ZnS, CdSSe, CdTeSe, CdSTe, ZnSSe, ZnSTe, ZnTeSe, or AIP.

An emission wavelength of the QD 51 can be changed in various manners depending on, for example, the size and the composition of the particle. The QD 51 emits visible light. A particle size and a composition of the QD 51 are appropriately adjusted so that the emission wavelength of the QD 51 can be controlled.

The EML 23R contains, as the QDs 51, red QDs that emit a red light. The EML 23G contains, as the QDs 51, green QDs that emit a green light. The EML 23B contains, as the QDs 51, blue QDs that emit a blue light. The same light-emitting elements ES (i.e., the same pixels P) contain the same kind of QDs. Note that, in this embodiment, in a case where the red QDs, the green QDs, and the blue QDs do not have to be particularly distinguished from one another, the red QDs, the green QDs, and the blue QDs are collectively referred to as “QDs 51”.

As illustrated in FIG. 2, the ligands 52 are found in large number outside the QDs 51. These ligands 52 are coordinated to the surface (or near the surface) of the QDs 51. The ligands 52 coordinated to the surface (i.e., near the surface) of the QDs 51 can keep the QDs 51 from agglomerating together. Hence, target optical properties are easily expressed.

Note that, in this embodiment, the “ligands” are a compound having a coordinating function. If the EML 23 contains both the QDs 51 and the ligands 52, at least some of the ligands 52 are assumed to be coordinated to the QDs 51. Furthermore, the statement “coordinated” means that the ligands 52 are either adsorbed on the surface of the QDs 51 or found around the QDs 51 (i.e., the ligands 52 modify the surface of the QDs 51 (the ligands 52 surface-modify the QDs 51). Moreover, the statement “adsorbed” means that the concentration of the ligands 52 is higher on the surface of the QDs 51 than in the surroundings of the QDs 51. The adsorption may be chemisorption representing a chemical bond between the QDs 51 and the ligands 52. Alternatively, the adsorption may be either physisorption, or electrostatic adsorption. The ligands 52 may bond to the surface of the QDs 51 by, for example, coordinate boding, common bonding, ionic bonding, and hydrogen bonding as long as the adsorption of the ligands 52 chemically affect the surface of the QDs 51. Alternatively, the ligands 52 do not necessarily have to bond to the surface of the QDs 51. As can be seen, in this embodiment, the statement “ligand” collectively refers not only to a molecule or an ion coordinated to the surface of the QD 32 but also to a molecule or an ion that can be coordinated but is not coordinated.

Each of the functional layers included in the light-emitting element ES can be formed of a coat. Each functional layer can be formed by, for example, spin coating, vacuum evaporation, or inkjet printing.

The QDs 51 are dispersed in a solvent and applied. The ligands 52, coordinated to QDs 51, can disperse the QDs 51 in the solvent.

A ligand typically includes: a coordinating functional group (also referred to as an “adsorbing group”) coordinated to (adsorbed onto) the surface of a QD; and a carbon chain such as a hydrocarbon chain bonding to the coordinating functional group.

The ligands 52 shall not be limited to particular ligands as long as the ligands can disperse the QDs 51 in the solvent. The ligands 52 may include known various ligands. Example of a ligand 52 includes a ligand having at least one coordinating functional group described above. The coordinating functional group may be a functional group coordinatable to a QD 51. Examples of the coordinating functional group typically include a thiol group, an amino group, a carboxyl group, a phosphone group, and a phosphine group.

The solvent may be any given solvent as long as the solvent allows the QDs 51 to disperse in the presence of the ligands 52. In order not to dissolve a functional layer serving as an underlayer of the QDs 51, the solvent is preferably less likely to dissolve the underlayer (i.e., an orthogonal solvent with respect to the underlayer). Hence, in this embodiment, the solvent preferably has both a polarity term δP and a hydrogen bonding term δH of 0 among the Hansen solubility parameter HSP values. The solvent preferably contains 80 vol % or more of a solvent having both the polarity term δP and the hydrogen bonding term δH of 0.

Specific examples of the solvent include octane and hexane.

Hence, the ligands 52 are preferably nonpolar ligands. The nonpolar ligands exhibit a high polarity in a free state in which the nonpolar ligands are not coordinated to the QDs 51, because of the polarity of the coordinating functional groups. Whereas, the nonpolar ligands exhibit a low polarity or no polarity in a coordination state in which the nonpolar ligands are coordinated to the QDs 51, because the polarity of the coordinating functional groups is cancelled by QDs 51. Hence, the QDs 51 coordinated with the nonpolar ligands are likely to be dispersed in a solvent having both the polarity term δP and the hydrogen bonding term δH of 0. Hence, when the nonpolar ligands are used as the ligands 52, a QD-dispersed liquid using the above solvent is applied to successfully form the EML 23.

In order to apply the nano-LED technique to, for example, a full-color display device as described above, the EML 23 needs to be colored in at least three colors of, for example, red, green, and blue as illustrated in FIG. 1. In this embodiment, the QD-LiXer technique is used for forming the EML 23.

In order to form the EML 23, first, a QD-dispersed liquid containing: the QDs 51; the ligands 52; the photo-crosslinking agent 53; and the solvent is applied to the first functional layer serving as an underlayer of the EML 23. The applied QD-dispersed liquid is dried to form a QD-containing film. In the example illustrated in FIG. 1, the first functional layer is the HTL 22. The QD-containing film, which is dried so that the solvent is removed, contains: the QDs 51; the ligands 52; and the photo-crosslinking agent 53. Next, the QD-containing film is partially irradiated with, and exposed to, light (i.e., an active energy ray) such as ultraviolet (UV) light. Hence, ligands 52 on a surface of the QDs 51 in the light-exposed portion are crosslinked (i.e., photo-crosslinked) with the photo-crosslinking agent 53. This crosslinking cures the QD-containing film in the light-exposed portion. After that, a non-light-exposed portion neither crosslinked nor cured is dissolved with a developing solution and removed. Thus, the EML 23 is successfully formed.

Note that, in this embodiment, the term “photo-crosslinking agent” is a compound capable of crosslinking when irradiated with, and exposed to, light (i.e., an active energy ray) such as UV light. In this embodiment, as long as a compound is capable of crosslinking when exposed to light as described above, the compound is referred to as a “photo-crosslinking agent” whether or not crosslinked as illustrated in FIG. 2. Hence, in this embodiment, a photo-crosslinked compound and a compound photo-crosslinkable but not crosslinked (photo-crosslinked) yet are correctively referred to as a “photo-crosslinking agent”.

The QD-containing film containing the photo-crosslinking agent 53 can be patterned by a simple solution process of development.

The photo-crosslinking agent 53 shall not be limited to a particular crosslinking agent as long as the crosslinking agent contains a photoreactive group capable of crosslinking the ligands 52 when irradiated with, and exposed to, such light as UV light. The photo-crosslinking agent 53 can be, for example, any various known photo-crosslinking agents used for the QD-LiXer technique. The photo-crosslinking agent 53 is preferably polyazide containing two or more azide (—N3) groups or nitrene (—N:) groups as photoreactive groups.

An azide group is activated to a nitrene group by light (i.e., an active energy ray) such as UV light, and the nitrene group bonds to, and crosslinks (i.e., photo-crosslink), a ligand 52. Polyazide containing two or more azido groups or nitrene groups can crosslink any given ligands 52 containing a C—H bond.

Polyazide not activated by exposure to light contains two or more azide groups in one molecule. Hence, when polyazide is used as the photo-crosslinking agent 53, the polyazide contained in the QD-dispersed liquid and in the QD-containing film unexposed to light contains two or more azide groups as photoreactive groups in one molecule.

Because the QD-containing film contains polyazide containing two or more azide groups in one molecule, the QD-containing film can be patterned by a simple solution process of development. Thus, polyazide is used as the photo-crosslinking agent 53. Such a feature makes it possible to obtain the EML23 in which the ligands 52 are crosslinked with polyazide.

The azide groups activated by exposure to light becomes nitrene groups as described above. Hence, polyazide activated by exposure to light has at least one of the two or more azide groups become a nitrene group. Thus, polyazide contains at least one nitrene group.

Thus, the light-exposed portion of the QD-containing film exposed to light and at least some of polyazide contained in the EML 23 have nitrene groups, and crosslink the light-exposed portion or at least some of the ligands 52.

Note that, not all the photo-crosslinking agent 53 contained in the EML 23 has to crosslink the ligands 52. As illustrated in FIG. 2, the EML 23 may have some of the photo-crosslinking agent 53 not involved in crosslinking.

The EML 23 may contain polyazide having only one of the photoreactive groups bonding to a ligand 52, or may contain polyazide not bonding to the ligands 52. Hence, polyazide contained in the EML 23 may be either polyazide containing two or more azide groups in one molecule, or polyazide containing two or more nitrene groups in one molecule. Furthermore, polyazide may contain one or more azide groups and one or more nitrene groups in one molecule.

Note that FIG. 2 exemplifies a case where the photo-crosslinking agent 53 has two photoreactive groups. Alternatively, the photo-crosslinking agent 53 may have three or more photoreactive groups.

Examples of the polyazide contained in the EML 23 include at least one selected from the group consisting of compounds represented by Formulae (1) to (10) below:

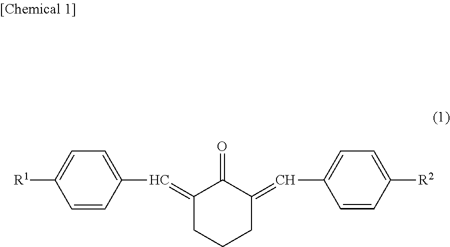

wherein each of R¹ and R² independently represents an azide group or a nitrene group;

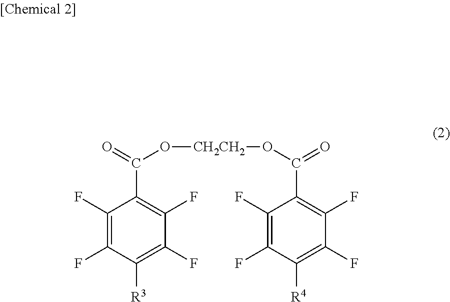

wherein each of R³ and R⁴ independently represents an azide group or a nitrene group;

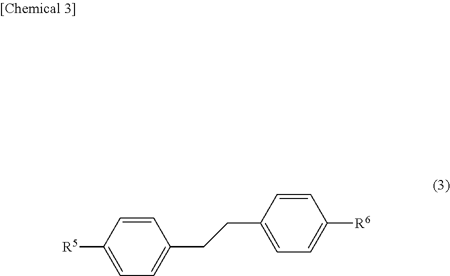

wherein each of R⁵ and R⁶ independently represents an azide group or a nitrene group;

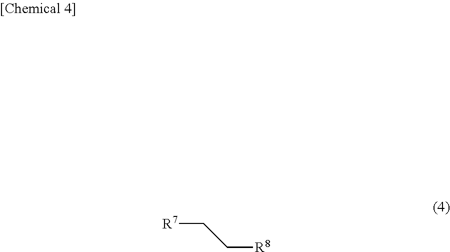

wherein each of R⁷ and R⁸ independently represents an azide group or a nitrene group;

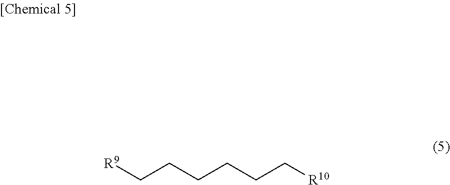

wherein each of R⁹ and R¹⁰ independently represents an azide group or a nitrene group;

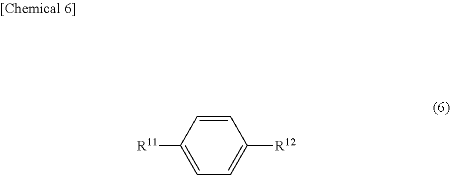

wherein each of R¹¹ and R¹² independently represents an azide group or a nitrene group;

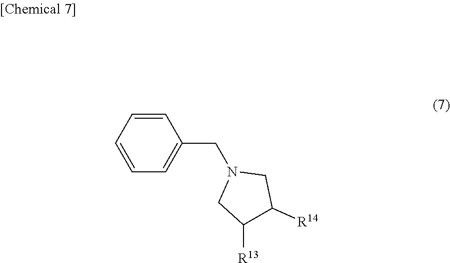

wherein each of R¹³ and R¹⁴ independently represents an azide group or a nitrene group;

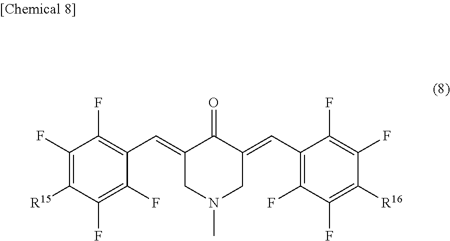

wherein each of R¹⁵ and R¹⁶ independently represents an azide group or a nitrene group;

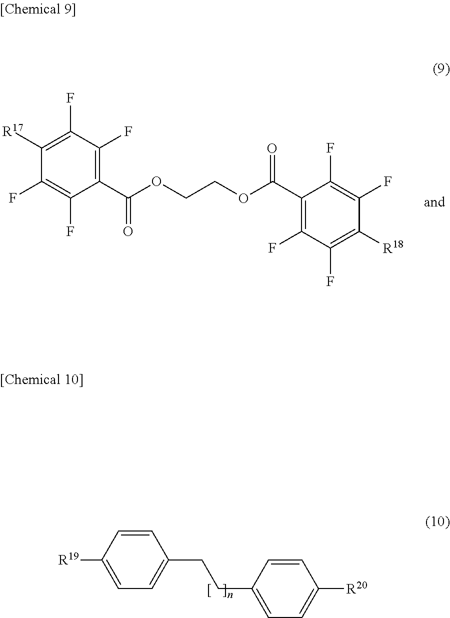

wherein each of R¹⁷ and R¹⁸ independently represents an azide group or a nitrene group;
wherein each of R¹⁹ and R²⁰ independently represents an azide group or a nitrene group, and n represents either 0 or 1.

Polyazide contained in the EML 23 desirably contains at least one selected from the group consisting of these compounds. The polyazide contains at least one selected from the group consisting of the above compounds. Such a feature makes it possible to easily obtain the EML23 in which at least some of the ligands 52 are crosslinked with polyazide.

When the EML 23 contains the polyazide, examples of the polyazide used for the QD-dispersed liquid include: 2,6-bis(4-azidobenzylidene)cyclohexanone (abbreviated as BABC) wherein R¹ and R² in Formula (1) are azide groups; ethane-1,2-diylbis(4-azido-2,3,5,6-tetrafluorobenzoate) wherein R³ and R⁴ in Formula (2) are azide groups; 4,4′-diazidodiphenylethane wherein R⁵ and R⁶ in Formula (3) are azide groups; 1,2-diazidoethane wherein R⁷ and R⁸ in Formula (4) are azido groups; 1,6-diazidohexane wherein R⁹ and R¹⁰ in Formula (5) are azide groups; 1,4-diazidobenzene wherein R¹¹ and R¹² in Formula (6) are azide groups; (3S,4S)-3,4-diazido-1-(phenylmethyl) pyrrolidine or (3R,4R)-(−)-3,4-diazido-1-(phenylmethyl) pyrrolidine wherein R¹³ and R¹⁴ in Formula (7) are azide groups; (3E,5E)-3,5-bis(4-azido-2,3,5,6-tetrafluorobenzylidene)-1-methylpiperidine-4-one wherein R¹⁵ and R¹⁶ in Formula (8) are azide groups; bis(4-azido-2,3,5,6-tetrafluorobenzoic acid) in which R¹⁷ and R¹⁸ in Formula (9) are azide groups; and a compound wherein R¹⁹ and R²⁰ in Formula (10) are azide groups (e.g., 1,1′-methylenebis(4-azidobenzene) wherein n=0, and 4,4′-diazidodiphenylethane wherein n=1).

Note that, as described before, the photo-crosslinking agent 53 may be a crosslinking agent containing a photoreactive group capable of crosslinking the ligands 52 when exposed to light. Examples of such a photo-crosslinking agent include diazirine and polyaziridine, other than polyazide. Hence, the photo-crosslinking agent 53 desirably contains polyazide; however, the photo-crosslinking agent 53 may contain a photo-crosslinking agent other than polyazine, such as diazirine or polyaziridine. The photo-crosslinking agent 53 may be used alone. Alternatively, two or more photo-crosslinking agents may be appropriately combined as the photo-crosslinking agent 53.

Furthermore, the photo-crosslinking agent 53 such as polyazide may be substituted with fluorine in order to improve efficiency of crosslinking reaction.

Note that, in the QD-dispersed liquid, the QD-containing film, and the EML 23, a content of the ligands 52 to the QDs 51 and a content of the photo-crosslinking agent 53 to the ligands 52 may be set appropriately in accordance with kinds of the ligands 52 and the photo-crosslinking agent 53. The contents shall not be limited to particular contents.

Furthermore, in the QD-dispersed liquid, concentrations of the QDs 51, the ligands 52, and the photo-crosslinking agent 53 may be set so that the QD-containing film has a desirable thickness. The concentrations shall not be limited to particular concentrations.

In the QD-LiXer technique, as described before, a photo-crosslinking agent is added to QDs. Then, ligands on the surface of the QDs are exposed to light and crosslinked, and an uncrosslinked non-light-exposed portion is dissolved with a developing solution and removed. Hence, the QD-LiXer technique can pattern the EML with fewer steps than such a technique as the lift-off technique can. Furthermore, the QD-LiXer technique eliminates the need of a sacrificial layer such as a resist when patterning the EML. In view of these points, the QD-LiXer technique is superior to known photolithography techniques such as the lift-off technique.

However, the QD-LiXer technique has a difficulty in removing all the QDs in the non-light-exposed portion during the development. As described above, when the QD-LiXer technique is used for patterning the EML, the photo-crosslinking agent binds the QDs to the first functional layer serving as an underlayer of the EML, and a residue of the EML might be left in a region where the EML is supposed to be patterned and removed. Such a residue causes decreases in the performance and color purity of a light-emitting device such as a display device.

In particular, if the light-emitting device is a display device as described above, the residue of the EML causes color mixture. Furthermore, if the residue of the EML is left in large amount, for example, two EMLs might be formed. Here, a region is generated to have locally different voltage-current characteristics. Such a region causes a deterioration in performance of the display device, such as a failure to display with a predetermined gradation, and a reduction in efficiency in releasing light and the resulting dark portion appearing locally.

Hence, in this embodiment, the first functional layer and the EML 23 are patterned at once. For this purpose, this embodiment involves: stacking a first functional film, which is photocurable, to serve as the first functional layer and a QD-containing film to serve as the EML 23; exposing, with light, regions of the first functional film and the QD-containing film to be left as patterns; and removing non-light-exposed portions of the first functional film and the QD-containing film at once. In other words, the non-light-exposed portions of the first functional film and the QD-containing film are removed in parallel by development.

Note that, here, in the first functional film and the QD-containing film, the regions to be left as patterns are: a prospective EML-forming region (a first region) in the QD-containing film; and a region (a second region) included in the first functional film and overlapping with the first region.

As can be seen, in this embodiment, an unnecessary QD-containing film is removed together with the underlayer. Such a feature makes it possible to leave no residue of the EML in a region from which the EML is supposed to be removed (i.e., a region from which the QD-containing film is supposed to be removed after patterning). As a result, the display device 1 can be manufactured to have high performance.

In this embodiment, the first functional layer is patterned by exposure to light and development. Hence, the first functional film is formed of a photocurable compound that cures when irradiated with light. The first functional film is a photocurable-compound-containing film that is a film containing a photocurable compound.

When the first functional film is exposed to light, the photocurable compound is cured to form a photocurable resin. Hence, in this embodiment, the first functional layer serving as the underlayer of the EML 23 is provided between the lower electrode and the EML 23, and adjacent to the EML23. The first functional layer contains a photocurable resin.

The above photocurable compound is a photopolymerizable monomer having a photocurable functional group. The above photocurable compound shall not be limited to a particular kind of photocurable compound as long as: the photocurable compound can be polymerized (photopolymerized) and cured (photocured) by an action of light (i.e., an active energy ray) such as UV light or an action of the light and a photopolymerization initiator; and the photocurable compound becomes insoluble in a developing solution when cured.

Note that the QD-containing film is, as described above, formed of the QD-dispersed liquid applied to the first functional film. As described before, the solvent to be preferably used for depositing the QD-containing film contains 80 vol % or more of a solvent having both a polarity term δP and a hydrogen bonding term δH of 0 among the Hansen solubility parameter HSP values.

Hence, the first functional layer and the first functional film are desirably insoluble in the solvent containing 80 vol % or more of a solvent having both a polarity term δP and a hydrogen bonding term δH of 0 among the HSP values.

The photocurable monomer may be either a radical polymerizable monomer or a cationic polymerizable monomer.

Furthermore, a light source for photocuring the photocurable compound shall not be limited to a particular light source as long as the light source emits light having absorption wavelengths of the photocurable compound and the photopolymerization initiator to be used.

However, the photo-crosslinking agent 53 and either the photocurable compound or the photocurable resin are preferably formed of a material to be activated by light having an equal wavelength.

In such a case, the EML 23 and the first functional layer can be exposed to light, developed, and patterned at once. Such a feature makes it possible to provide the display device 1 easily at low costs, with no residue of the EML left in a region from which the EML is supposed to be removed after patterning.

Note that the light is preferably UV light. Hence, examples of the above photocurable compound include what is referred to as an ultraviolet-curable compound whose photopolymerization reaction is encouraged upon irradiation with UV light such that the ultraviolet-curable compound cures. In such a case, the EML 23 and the first functional layer can be patterned at once, using UV light. Such a feature makes it possible to provide the display device 1 easily at low costs, with no residue of the EML left in a region from which the EML is supposed to be removed after patterning.

In the display device 1 illustrated in FIG. 1, the first functional layer used as the underlayer of the EML 23 is the HTL 22 as described before. The HTL 22 is a charge transport layer containing a hole transporting material and having a hole transporting function to enhance efficiency in transporting the holes to the EML 23.

In this embodiment, the HTL 22 is a photocurable HTL. Hence, in this embodiment, the HTL 22 is formed of, for example, a photocurable compound capable of transporting the holes. Thus, a hole transport film (the first functional film), which becomes the HTL 22 and is not exposed to light, contains the photocurable compound capable of transporting the holes.

Examples of the photocurable compound include: N,N′-bis(4-(6-((3-ethyloxetane)-3-yl)methoxy))-hexylphenyl)-N,N′-diphenyl-4,4′-diamine (abbreviated as OTPD) represented by Formula (11) below; and N4,N4′-bis(4-(6-((3-ethyloxetane)-3-yl)methoxy)hexyloxy)phenyl)-N4,N4′-bis(4-methoxyphenyl)biphenyl-4,4′-diamine (abbreviated as QUPD) represented by Formula (12) below. These photocurable compounds may be used alone, or in combination of two or more as appropriate.

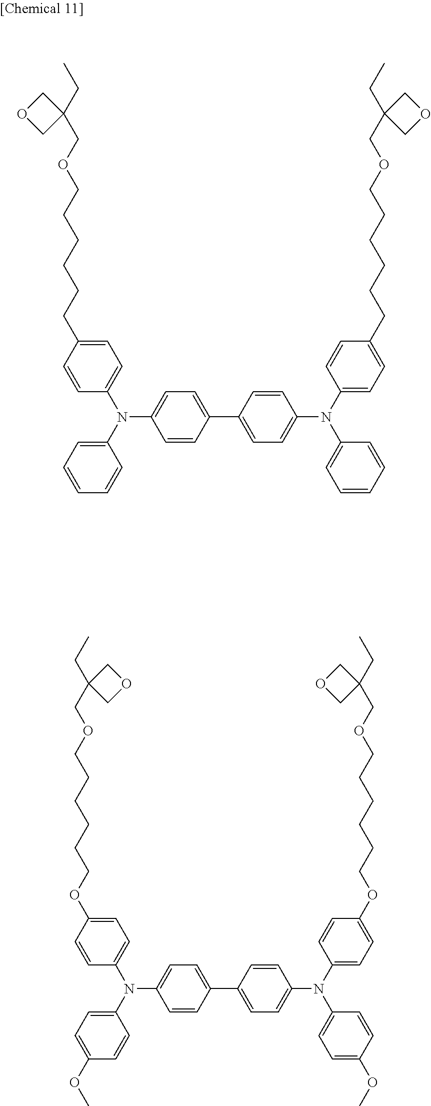 [SMILES: CCC1(COCCCCCCc2ccc(N(c3ccccc3)c3ccc(-c4ccc(N(c5ccccc5)c5ccc(CCCCCCOCC6(CC)COC6)cc5)cc4)cc3)cc2)COC1 ; CCC1(COCCCCCCOc2ccc(N(c3ccc(OC)cc3)c3ccc(-c4ccc(N(c5ccc(OC)cc5)c5ccc(OCCCCCCOCC6(CC)COC6)cc5)cc4)cc3)cc2)COC1]

These photocurable compounds are activated when irradiated with, and exposed to, light such as UV light. Thus, the photopolymerization reaction is encouraged, and the photocurable compounds cure. In particular, the OTPD and the QUPD have an oxetane group (i.e., an oxetane ring). The OTPD and the QUPD are photo-cationically polymerized by a cationic ring-opening polymerization, and three-dimensionally crosslinked and cured. Furthermore, when exposed to, for example, UV light having a wavelength of 365 nm, the OTPD and the QUPD are activated, polymerized, and crosslinked and cured. Note that the polyazide described before as an example is also activated by UV light having a wavelength of 365 nm, and the ligands 52 are crosslinked. Hence, the OTPD and the QUPD are particularly preferably used as the photocurable compounds.

As described before, each of the functional layers included in the light-emitting element ES can be formed of a coat. As described above, the first functional film is a photocurable-compound-containing film that can be formed of a photocurable-compound-containing liquid containing a photocurable compound and a solvent. The photocurable-compound-containing liquid is applied and dried to form the first functional film.

As described before, the first functional layer and the first functional film are insoluble in a solvent containing 80 vol % or more of a solvent to be used for a QD-dispersed liquid (e.g., a solvent containing 80 vol % or more of a solvent having both a polarity term δP and a hydrogen bonding term δH of 0 among the HSP values). Examples of the solvent to be used for the photocurable-compound-containing liquid include the PGMEA.

The first functional film contains the photocurable compound because, after the photocurable-compound-containing liquid is applied, the photocurable-compound-containing liquid is dried so that the solvent is removed. Note that, the photocurable-compound-containing liquid may further contain a photopolymerization initiator as necessary.

Hence, the first functional film and the first functional layer may further contain a photopolymerization initiator. Such a feature can encourage the photocurable compound to polymerize and the photocurable resin to cure when the first functional layer is formed, and simultaneously allows a curing condition of the photocurable resin to be readily controlled.

The photopolymerization initiator shall not be limited to a particular photopolymerization initiator as long as the photopolymerization initiator can initiate polymerization of the photocurable compound when the photocurable compound is irradiated with light.

The photopolymerization initiator may be either a radical polymerization initiator or a cationic polymerization initiator. When either the OTPD or the QUPD is used as the photocurable compound as described above, the photopolymerization initiator to be used is a cationic polymerization initiator such as, for example, p-octyloxy-phenyl-phenyliodonium hexafluoroantimonate (abbreviated as OPPI).

Note that a proportion of the photopolymerization initiator to the photocurable compound may be appropriately set so that the photocurable compound is cured, depending on the kinds of the photocurable compound and the photopolymerization initiator. Hence, the proportion shall not be limited to a particular proportion. Thus, similarly, a content of the photopolymerization initiator to the photocurable resin in the first functional film shall not be limited to a particular content.

Furthermore, a concentration of the photocurable compound in the photocurable-compound-containing liquid may be set so that the first functional film is obtained to have a desired thickness. Hence, the concentration shall not be limited to a particular concentration.

In this embodiment, as described above, the QD-containing film contains: the QDs 51, the ligands 52, and the photo-crosslinking agent 53. The first functional film provided adjacent to the QD-containing film and serving as an underlayer contains a photocurable compound. The first functional film and the QD-containing film are patterned at once. In the example illustrated in FIG. 1, the first functional film is a hole transport film to be used as the HTL 22.

Hence, as described above, the display device 1 according to this embodiment includes the plurality of pixels P serving as a light-emitting region, and each of the pixels P includes: a lower electrode; an upper electrode; and a plurality of functional layers stacked on top of another between the lower electrode and the upper electrode. The plurality of functional layers include at least: the EML 23 provided between the lower electrode and the upper electrode; and the first functional layer provided between the lower electrode and the EML, and adjacent to the EML 23. The first functional layer serves as an underlayer. The EML 23 contains: the QDs 51; the ligands 52; and the photo-crosslinking agent 53, and the first functional layer provided adjacent to the EML 23 contains a photocurable resin. In the example illustrated in FIG. 1, the first functional film is the HTL 22. Hence, in the display device 1 obtained in this embodiment, as illustrated in FIG. 1, an end face of the EML 23 and an end face of the HTL 22, which is the underlayer of the EML 23, are flush with each other. Thus, in plan view, the EML 23 and the HTL 22 are the same or similar (substantially the same) in shape.

According to this embodiment, the photo-crosslinking agent 53 is exposed to light and crosslinked. Thanks to such a feature, a non-light-exposed portion not crosslinked by development is dissolved, so that the EML 23 (i.e., the QD-containing film) can be patterned.

In the related art, when the EML contains a photo-crosslinking agent, a residue of the EML (i.e., a residue of the QD-containing film) is likely to be left on an underlayer of the EML; that is, a region from which the EML is supposed to be removed, after the EML 23 is patterned.

However, in this embodiment, the first functional layer, which is the underlayer of the EML 23, can be patterned together with the EML 23 by exposure to light and development. Thus, in the display device 1 according to this embodiment, the end face of the EML 23 and the end face of the first functional layer are flush with each other as described above. Hence, in the light-emitting device, the first functional layer can also be removed from the region from which the EML is removed. As a result, in the display device 1, even if the ligands 52 and the photocurable resin are crosslinked by the photo-crosslinking agent 53, the first functional layer is removed from the region from which the EML is removed, so that no residue of the EML is left in the region from which the EML is supposed to be removed. Such a feature reduces risks that the residue of the EML causes; that is, color mixture that reduces a color reproduction range, and performance decrease such as poor electrical connection.

Thus, according to this embodiment, no residue of the EML is left in a region from which the EML is supposed to be removed. Thanks to such a feature, the display device 1 can present excellent performance and color purity with no color mixture.

Note that the absence of the EML residue in the region from which the EML is supposed to be removed can be determined by checking, for example, color purity of each pixel P. Furthermore, if the residue is present, the EML becomes thick and the drive voltage rises. As a result, the EML might locally appear dark when observed with a microscope. Hence, in addition to color purity, the residue can be checked by visual observation with, for example, a microscope.

Moreover, components of the functional layers in the display device 1 (e.g., the photo-crosslinking agent 53 in the EML23 or in the QD-containing film, the photocurable compound in the first functional film, and the photocurable resin in the first functional layer) can be checked by gas chromatography, liquid chromatography, Fourier transform infrared spectroscopy, and nuclear magnetic resonance analysis.

In addition, as described above, the plurality of functional layers may include functional layers other than the first functional layer and the EML 23. The display device 1 illustrated in FIG. 1 includes, as described above, the HIL 21 and the ETL 24 serving as functional layers other than the HTL 22 serving as the first functional layer and the EML 23.

The HIL 21 contains a hole transporting material, and has a hole injection function to enhance efficiency in injecting the holes from the anode 11 into the HTL 22.

A hole transporting material of the HIL 21 shall not be limited to a particular material. The material can be any given various hole transporting materials used in the related art for HILs.

Examples of the hole transporting material to be used for the HIL 21 include a composite (PEDOT: PSS) containing poly(3,4-ethylenedioxythiophene) (PEDOT) and polystyrene sulphonate (PSS). Note that the hole transporting material may be used alone, or two or more kinds of hole transporting materials may be used in combination as appropriate.

Note that the HIL 21 and the HTL 22 may be formed as independent layers, or may be integrated as a hole injection-transport layer. Furthermore, the HIL 21 and the HTL 22 do not have to be provided simultaneously. The HTL 22 may be provided alone.

Note that the plurality of functional layers preferably include a second functional layer provided between the lower electrode and the first functional layer, and adjacent to a plurality of lower electrodes including the lower electrode. The second functional layer preferably covers the lower electrode. The end face of the EML 23 and the end face of the first functional layer are preferably positioned outside an end face of the lower electrode.

Here, above the lower electrode, the second functional layer and a layer provided above the EML 23 (e.g., either the upper electrode or a functional layer provided between the EML 23 and the upper electrode) are not in contact with each other. Such a feature can prevent electrical leakage at an interface between the second functional layer and the layer provided above the EML 23.

Hence, in the example illustrated in FIG. 1, the display device 1 preferably contains the HIL 21 serving as the second functional layer, and the HIL 21 preferably covers the anode 11.

The ETL 24 is a charge transport layer containing an electron transporting material and having an electron transporting function to enhance efficiency in transporting the electrons to the EML 23.

An electron transporting material to be used for the ETL 24 shall not be limited to a particular material. The material can be any given various electron transporting materials used in the related art for ETLs.

Examples of the electron transporting material to be used for the ETL 24 includes: 1,3,5 tris(1-phenyl-1H-benzimidazol-2-yl)benzene (TPBi); bathophenanthroline (Bphen); tris(2,4,6-trimethyl-3-(pyridin-3-yl)phenyl)borane (3TPYMB); ZnO nanoparticles; and MgZnO nanoparticles formed of ZnO nanoparticles doped with Mg. These electron transporting materials may be used alone, or in combination of two or more as appropriate.

Although not shown, as described above, the plurality of functional layers may include an EIL. The EIL contains an electron transporting material, and has an electron injecting function to enhance efficiency in injecting the electrons into the ETL 24. The EIL and the ETL 24 may be formed as independent layers, or may be integrated as an electron injection-transport layer. For example, ZnO nanoparticles excel in injecting electrons, and the ETL is often omitted (i.e., the EIL also serves as the ETL). Hence, the EIL and the ETL 24 do not have to be provided simultaneously. As illustrated in FIG. 1, the ETL 24 may be provided alone.

As described above, the light-emitting element layer 3 is covered with a not-shown sealing layer. The sealing layer is transparent to light, and formed of either an inorganic insulating film or a multilayer stack including an organic insulating film and an inorganic insulating film. Note that the sealing layer may be, for example, sealing glass. The sealing layer seals the light-emitting elements ES, thereby making it possible to prevent water and oxygen from penetrating into the light-emitting elements ES.

### Manufacturing Method

Described next will be a method for manufacturing the display device 1 according to this embodiment.

The method for manufacturing the display device 1 according to this embodiment includes: a lower electrode forming step; a functional layer forming step; and an upper electrode forming step. The lower electrode forming step involves forming a lower electrode for each of the pixels P. The functional layer forming step involves forming a plurality of functional layers above the lower electrode of each pixel P. The upper electrode forming step involves forming an upper electrode, across from the lower electrode, above the functional layers of each pixel P.

Furthermore, the functional layer forming step includes: a first-functional-film depositing step; a QD-containing-film depositing step; a QD-containing-film exposing step, a first-functional-film exposing step; and a patterning step. The first-functional-film depositing step involves depositing a photocurable-compound-containing film serving as the first functional film. The QD-containing-film depositing step involves depositing a QD-containing film above, and adjacent to, the first functional film. The QD-containing film contains: the QDs 51; the ligands 52; and the photo-crosslinking agent 53. The QD-containing-film exposing step involves exposing a first region, which is a portion of the QD-containing film, with light to activate the photo-crosslinking agent, and crosslinking the photo-crosslinking agent 53 and the ligands 52 in the first region. The first-functional-film exposing step involves exposing a second region, which is included in the first functional film and overlaps with the first region, with light to activate the photocurable compound, and curing the photocurable compound in the second region to form a photocurable resin. The patterning step involves developing to pattern the QD-containing film and the first functional film. Hence, the QD-containing film is patterned to form the EML 23, and the first functional film is patterned to form the first functional layer having an end face flush with an end face of the EML 23. The first functional film is, as described above, a photocurable-compound-containing film containing a photocurable compound. The first functional layer is, as described above, a photocurable-resin-containing layer containing a photocurable resin.

Note that any of the above steps are included in a step of forming the light-emitting element layer 3. Hence, described below will be a light-emitting-element-layer forming step of forming the light-emitting element layer 3 on the substrate 2. The substrate 2 may be formed at a substrate forming step before the light-emitting-element-layer forming step. Alternatively, a commercially available substrate may be used as the substrate 2. The step of forming the substrate 2 shall not be limited to a particular step. The step may be any given various kinds of methods known as methods for forming a backplane. For example, if the light-emitting device is a display device, forming the substrate 2 may involve forming TFTs on the insulating substrate so that the TFTs are positioned at the respective pixels of the display device.

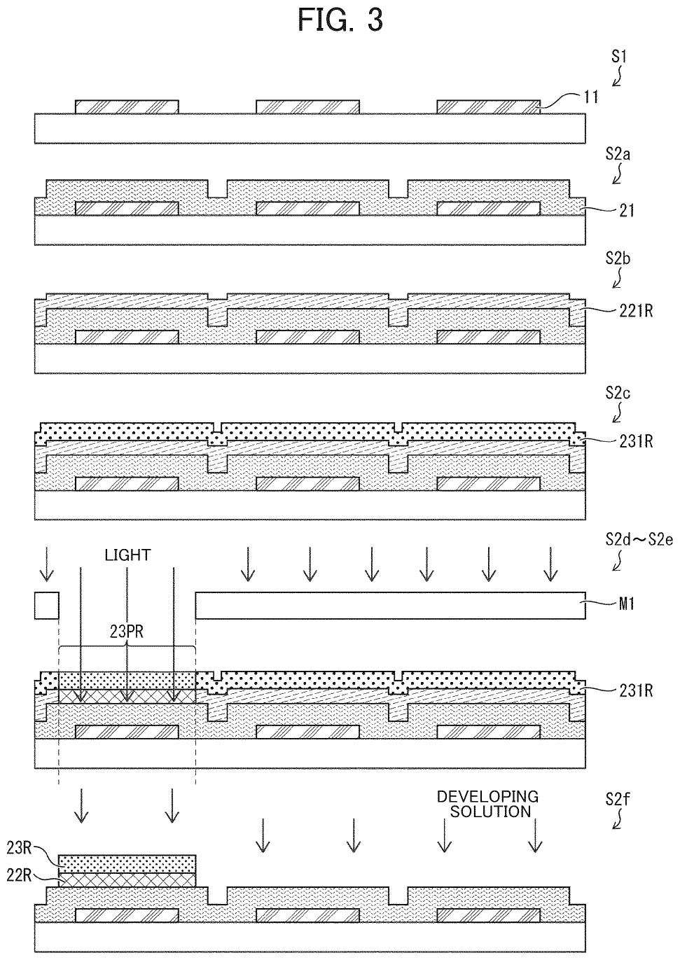

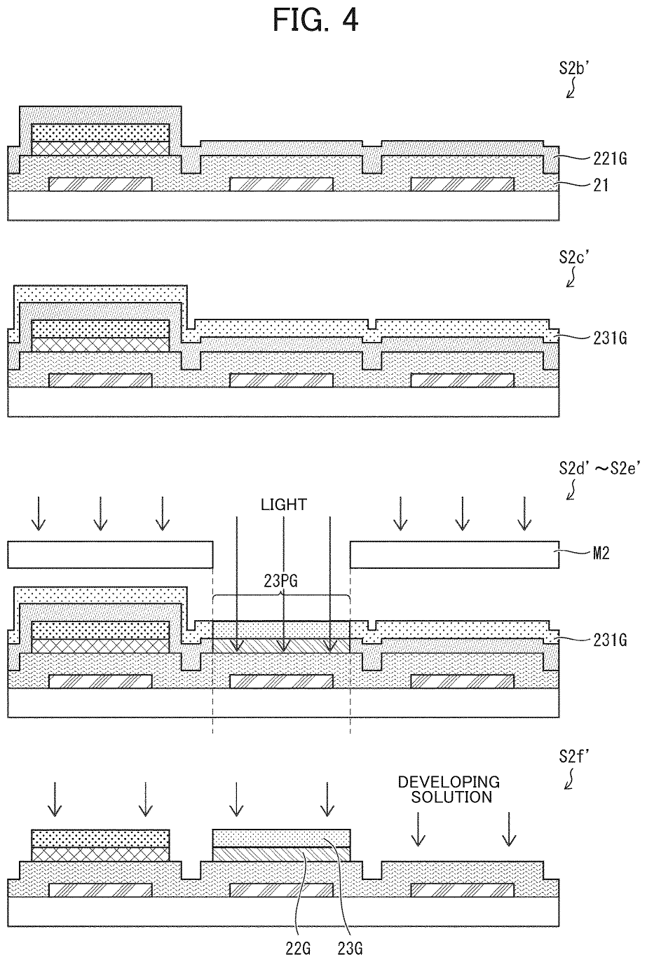

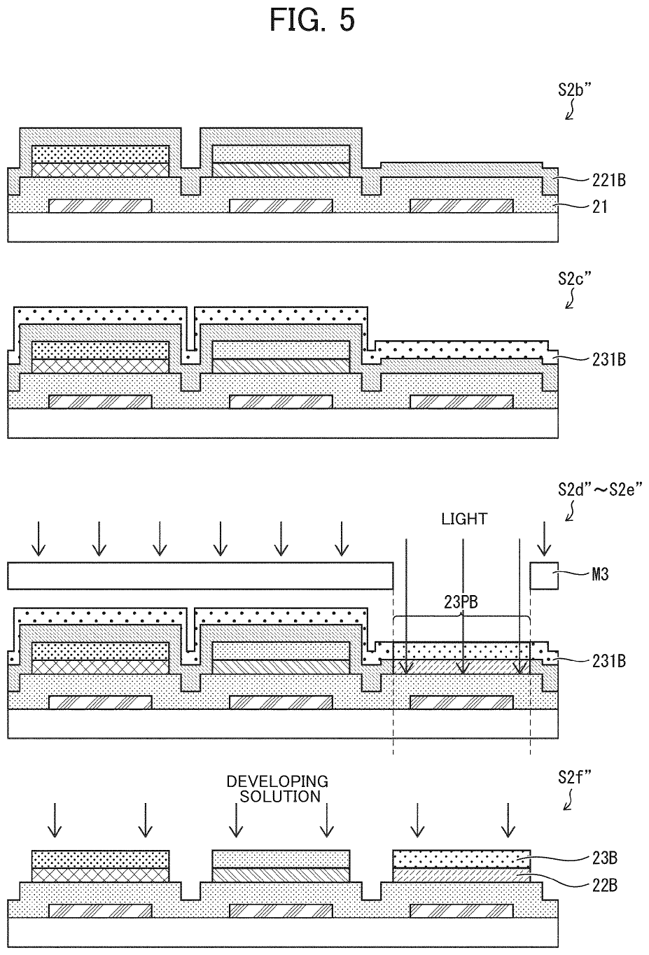

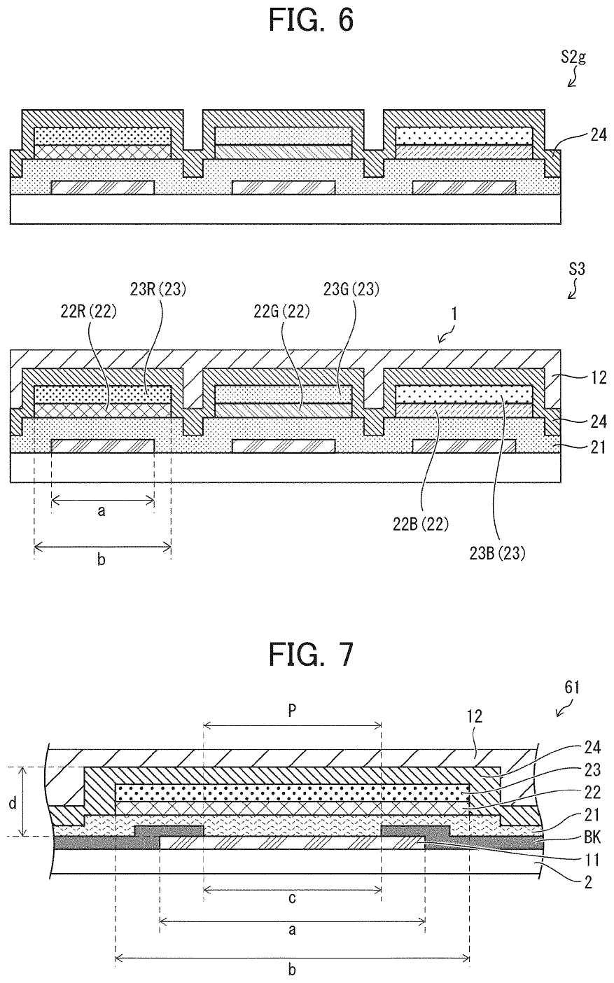

FIGS. 3 to 6 are cross-sectional views illustrating some steps of forming the light-emitting element layer 3 of the display device 1 illustrated in FIG. 1. FIG. 4 illustrates steps succeeding the steps illustrated in FIG. 3. FIG. 5 illustrates steps succeeding the steps illustrated in FIG. 4. FIG. 6 illustrates steps succeeding the steps illustrated in FIG. 5.

As illustrated in FIG. 3, at the light-emitting-element-layer forming step, first, each of the lower electrodes is formed on the substrate 2. Note that the lower electrodes are formed by the method previously described. In this embodiment, the anodes 11 are formed as described above to serve as the lower electrodes (Step S1: the lower electrode forming step).

Thus, a backplane, provided with the plurality of anodes 11 serving as the lower electrodes, is formed on the substrate 2 having the plurality of TFTs.

Next, above the lower electrodes, a plurality of functional layers are formed (Step S2: the functional layer forming step). In this embodiment, as illustrated in FIG. 1, the functional layers are the HIL 21, the HTL 22, the EML 23, and the ETL 24, all of which are stacked on top of another in the stated order above the anodes 11. Hence, Step S2 includes, for example, an HIL forming step to an ETL forming step to be described below. Furthermore, as will be exemplified below, Step S2 includes a step of forming at least some of the materials of the functional layers.

Note that described below will be a case where the EML 23R, the EML 23G, and the EML 23B are formed in the stated order. However, this embodiment shall not be limited to such a case. The EML 23R, the EML 23G, and the EML 23B may be formed in any given order.

In the display device 1 illustrated in FIG. 1, the HIL 21 and the ETL 24 are common layers provided in common to all the pixels P. Hence, at Step S2, first, the HIL 21 is formed (deposited) over the entire pixel region (i.e., the display region) so as to cover the anodes 11 (Step S2a: the HIL forming step).

Whereas, as an HTL material, a photocurable-compound-containing liquid is prepared (i.e., a photocurable-compound-containing-liquid manufacturing step). As described before, the photocurable-compound-containing liquid contains a photocurable compound, a solvent, and, as necessary, a photopolymerization initiator.

In this embodiment, the photocurable-compound-containing liquid is a mixed solution prepared to contain: 2 wt % of the OTPD as a photocurable compound dissolved in the PGMEA as a solvent; and 0.075 wt % of OPPI as a photopolymerization initiator added to the OTPD. As can be seen, the photocurable-compound-containing liquid is prepared before Step S2b.

Subsequently, the photocurable-compound-containing liquid is used to deposit a photocurable-compound-containing film 221R (i.e., the first functional film) on the HIL 21 (Step S2b: a first photocurable-compound-containing film depositing step, a first-functional-film first-depositing step). The photocurable-compound-containing film 221R is a photocurable film, and serves as an underlayer of the EML 23R. The photocurable-compound-containing film 221R contains the photocurable compound, and becomes the HTL 22R. As described above, if the photocurable-compound-containing liquid contains the photopolymerization initiator, the photocurable-compound-containing film 221R also contains the photopolymerization initiator.

In this embodiment, the photocurable-compound-containing liquid is applied to the HIL 21. After that, the solvent contained in the applied photocurable-compound-containing liquid is removed. Thus, the photocurable-compound-containing film 221R is deposited. Note that the photocurable-compound-containing liquid can be applied by such techniques as, for example, spin coating, slit coating, and inkjet printing.

On the other hand, a red-QD-dispersed liquid is prepared to contain red QDs as the QDs 51 (i.e., a red-QD-dispersed liquid manufacturing step). The red-QD-dispersed liquid contains: the red QDs; the ligands 52; the photo-crosslinking agent 53; and a solvent.

In this embodiment, the red QDs are InP-based QDs, and the ligands 52 are either oleic acid or dodecanethiol. Furthermore, the photo-crosslinking agent 53 is the BABC, and the solvent is a mixed solvent of octane and anisole mixed together at a ratio of 1:1. In this embodiment, the red-QD-dispersed liquid is prepared to contain: 20 g/L of the red QDs dispersed in the solvent; the ligands 52; and 0.125 wt % of the BABC, which serves as the photo-crosslinking agent 53, with respect to 1 wt % of the red QDs. As can be seen, the QD-dispersed liquid is prepared before the QD-containing-film depositing step.

Subsequently, the red-QD-dispersed liquid is used to deposit a QD-containing film 231R; that is, a red-QD-containing film (Step S2c: a red-QD-containing-film depositing step). The QD-containing film 231R, which becomes the EML 23R, contains the red QDs as the QDs 51, the ligands 52, and the photo-crosslinking agent 53.

In this embodiment, the red-QD-dispersed liquid is applied to the photocurable-compound-containing film 221R. After that, the solvent contained in the applied red-QD-dispersed liquid is removed. Hence, the QD-containing film 231R is deposited.

Next, the QD-containing film 231R included in the red prospective EML-forming region 23PR is irradiated with light (i.e., an active energy ray) that activates the photo-crosslinking agent 53. Thus, the photo-crosslinking agent 53 and the ligands 52 in the red prospective EML-forming region 23 PR are crosslinked (Step S2d: a red-QD-containing-film exposing step). Note that, here, the red prospective EML-forming region 23PR of the QD-containing film 231R is a portion of the QD-containing film 231R, and indicates a prospective region in which the EML 43R is to be formed.

Subsequently, a region (i.e., the second region) included in the photocurable-compound-containing film 221R and overlapping with the red prospective EML-forming region 23PR is irradiated with light (i.e., an active energy ray) that activates the photocurable compound. Thus, the photocurable compound included in the second region is cured to form the photocurable resin (Step S2e: a first photocurable-compound-containing-film exposing step, a first-functional-film first-exposing step).

The photocurable compound and the photo-crosslinking agent 53 are materials to be activated by light having an equal wavelength. Hence, in this embodiment, at Steps S2d and S2e, the first region and the second region are irradiated with light having the equal wavelength, so that Steps S2d and S2e are carried out in parallel.

When the first region and the second region are exposed to light, a single photomask M1 is used. At Steps S2d and S2e, for example, the photomask M1 is used. The photomask M1 includes an opening (i.e., an optical opening) so that, in plan view, the photomask M1 has: a portion corresponding to the red prospective EML-forming region 23PR of the red pixel PR and transparent to light; and another portion impervious to light. Thanks to such a feature, each of the first region of the QD-containing film 231R and the second region of the photocurable-compound-containing film 221R can be irradiated with the light.

In this embodiment, as an example, each of the first region of the QD-containing film 231R and the second region of the photocurable-compound-containing film 221R is irradiated with UV light having a peak wavelength of 365 nm at a luminous intensity of 13 mW/cm² for 15 seconds, using the same UV emitting apparatus. Hence, the ligands 52 in the first region are crosslinked by the photo-crosslinking agent 53, and the photocurable compound in the second region is cured to form the photocurable resin.

Next, the QD-containing film 231R and the photocurable-compound-containing film 221R are developed and patterned (Step S2f: a first patterning step). At the first patterning step, a portion except the first region and the second region (i.e., a non-light-exposed region including an uncrosslinked region of the QD-containing film 231R and an uncured region of the photocurable-compound-containing film 221R) is removed.

Hence, the QD-containing film 231R is patterned to form the EML 23R and the photocurable-compound-containing film 221R is patterned to form the HTL 22R, so that an end face of the EML 23R and an end face of the HTL 22R are flush with each other. As can be seen, Steps S2b to S2f form the EML 23R and the HTL 22R to have their respective end faces flush with each other. The EML 23R overlaps the HTL 22R. For example, in plan view, the EML 23R and the HTL 22R are the same or similar (substantially the same) in shape.

Note that the developing solution shall not be limited to a particular developing solution as long as the developing solution can remove the non-light-exposed portion including the uncrosslinked region of the QD-containing film 231R and the uncured region of the photocurable-compound-containing film 221R. Examples of the developing solution includes the PGMEA and toluene.

Next, the EML 23G and the ETL 24 are formed in the green pixel PG, and the EML 23B and the ETL 24 are formed in the blue pixel PB. Hence, the first-functional-film depositing step to the patterning step are set as one cycle, and the steps similar to Steps S2b to S2f are repeated two cycles so that three cycles are carried out in total. Note that, as the QDs 51, the green QDs are used in the second cycle, and the blue QDs are used in the third cycle.

Specifically, after the Step S2f, as illustrated in FIG. 4, for example, the photocurable-compound-containing liquid is used to deposit a photocurable-compound-containing film 221G (i.e., the first functional film) on the HIL 21 (Step S2b′: a second photocurable-compound-containing film depositing step, a first-functional-film second-depositing step). The photocurable-compound-containing film 221G is a photocurable film, and serves as an underlayer of the EML 23G. The photocurable-compound-containing film 221G contains the photocurable compound, and becomes the HTL 22G. As described before, if the photocurable-compound-containing liquid contains the photopolymerization initiator, the photocurable-compound-containing film 221G also contains the photopolymerization initiator.

In this embodiment, the photocurable-compound-containing liquid is applied to the HIL 21 to cover the HTL 22R and the EML 23R formed above the HIL 21. After that, the solvent contained in the applied photocurable-compound-containing liquid is removed. Thus, the photocurable-compound-containing film 221G is deposited.

On the other hand, a green-QD-dispersed liquid is prepared to contain green QDs as the QDs 51 (i.e., a green-QD-dispersed liquid manufacturing step). The green-QD-dispersed liquid contains: the green QDs; the ligands 52; the photo-crosslinking agent 53; and a solvent.

Note that, at the green-QD-dispersed liquid manufacturing step, InP-based QDs smaller in particle diameter than the red QDs are used as the green QDs instead of the red QDs. Otherwise, at the green-QD-dispersed liquid manufacturing step, the green-QD-dispersed liquid is made of the same materials as those of the red-QD-dispersed liquid in the same operations as those for the red-QD-dispersed liquid manufacturing step.

Subsequently, the green-QD-dispersed liquid is used to deposit a QD-containing film 231G; that is, a green-QD-containing film (Step S2c′: a green-QD-containing-film depositing step). The QD-containing film 231G, which becomes the EML 23G, contains the green QDs as the QDs 51, the ligands 52, and the photo-crosslinking agent 53.

In this embodiment, the green-QD-dispersed liquid is applied to the photocurable-compound-containing film 221G. After that, the solvent contained in the applied green-QD-dispersed liquid is removed. Hence, the QD-containing film 231G is deposited.

Next, the QD-containing film 231G in the green pixel PG is irradiated with light (i.e., an active energy ray) that activates the photo-crosslinking agent 53. As a result, a green prospective EML-forming region 23PG (the first region) of the QD-containing film 231G is irradiated with the light. Note that, here, the green prospective EML-forming region 23PG of the QD-containing film 231G is a portion of the QD-containing film 231G, and indicates a prospective region in which the EML 43G is to be formed. Hence, the photo-crosslinking agent 53 and the ligands 52 in the green prospective EML-forming region 23PG are crosslinked (Step S2d′: a green QD-containing-film exposing step).

Subsequently, the photocurable-compound-containing film 221G in the green pixel PG is irradiated with light (i.e., an active energy ray) that activates the photocurable compound. Hence, a region (i.e., the second region) included in the photocurable-compound-containing film 221G and overlapping with the green prospective EML-forming region 23PG is irradiated with the light. Note that, here, the second region included in the photocurable-compound-containing film 221G indicates a prospective HTL-forming region included in the photocurable-compound-containing film 221G and provided for the green pixel PG. Thus, the photocurable compound included in the second region is cured to form the photocurable resin (Step S2e′: a second photocurable-compound-containing-film exposing step, a first-functional-film second-exposing step).

As described before, the photocurable compound and the photo-crosslinking agent 53 are materials to be activated by light having the same wavelength. Hence, in this embodiment, at Steps S2d′ and S2e′, the first region and the second region are irradiated with light having the same wavelength. Thus, Steps S2d′ and S2e′ are carried out in parallel.

When the first region and the second region are exposed to light, a single photomask M2 is used. At Steps S2d′ and S2e′, for example, the photomask M2 is used. The photomask M2 includes an opening (i.e., an optical opening) so that, in plan view, the photomask M2 has: a portion corresponding to the green prospective EML-forming region 23PG of the green pixel PG and transparent to light; and another portion impervious to light. Thanks to such a feature, each of the first region of the QD-containing film 231G and the second region of the photocurable-compound-containing film 221G can be irradiated with the light.

In this embodiment, as can be seen at Steps S2d and S2e, each of the first region of the QD-containing film 231G and the second region of the photocurable-compound-containing film 221G is irradiated with UV light having a peak wavelength of 365 nm at a luminous intensity of 13 mW/cm² for 15 seconds, using the same UV emitting apparatus. Hence, the ligands 52 in the first region are crosslinked by the photo-crosslinking agent 53, and the photocurable compound in the second region is cured to form the photocurable resin.

Next, the QD-containing film 231G and the photocurable-compound-containing film 221G are developed and patterned (Step S2f′: a second patterning step). At the second patterning step, a portion except the first region and the second region (i.e., a non-light-exposed region including an uncrosslinked region of the QD-containing film 231G and an uncured region of the photocurable-compound-containing film 221G) is removed.

Hence, the QD-containing film 231G is patterned to form the EML 23G and the photocurable-compound-containing film 221G is patterned to form the HTL 22G, so that an end face of the EML 23G and an end face of the HTL 22G are flush with each other. As can be seen, Steps S2b′ to S2f form the EML 23G and the HTL 22G to have their respective end faces flush with each other. The EML 23G overlaps the HTL 22G. For example, in plan view, the EML 23G and the HTL 22G are the same or similar (substantially the same) in shape.

Note that the developing solution shall not be limited to a particular developing solution as long as the developing solution can remove the non-light-exposed portion including the uncrosslinked region of the QD-containing film 231G and the uncured region of the photocurable-compound-containing film 221G. The developing solution may be, for example, the developing solution described before as an example.

Next, after the Step S2f′, as illustrated in FIG. 5, for example, the photocurable-compound-containing liquid is used to deposit a photocurable-compound-containing film 221B (i.e., the first functional film) on the HIL 21 (Step S2b″: a third photocurable-compound-containing film depositing step, a first-functional-film third-depositing step). The photocurable-compound-containing film 221B is a photocurable film, and serves as an underlayer of the EML 23B. The photocurable-compound-containing film 221B contains the photocurable compound, and becomes the HTL 22B. As described before, if the photocurable-compound-containing liquid contains the photopolymerization initiator, the photocurable-compound-containing film 221B also contains the photopolymerization initiator.

In this embodiment, the photocurable-compound-containing liquid is applied to the HIL 21 to cover the HTL 22R, the EML 23R, the HTL 22G, and the EML 23G formed above the HIL 21. After that, the solvent contained in the applied photocurable-compound-containing liquid is removed. Thus, the photocurable-compound-containing film 221B is deposited.

On the other hand, a blue-QD-dispersed liquid is prepared to contain blue QDs as the QDs 51 (i.e., a blue-QD-dispersed liquid manufacturing step). The blue-QD-dispersed liquid contains: the blue QDs; the ligands 52; the photo-crosslinking agent 53; and a solvent.

Note that, at the blue-QD-dispersed liquid manufacturing step, ZnSe-based QDs are used as the blue QDs instead of the red QDs or the green QDs. Otherwise, at the blue-QD-dispersed liquid manufacturing step, the blue-QD-dispersed liquid is made of the same materials as those of the red-QD-dispersed liquid or the green-QD-dispersed liquid in the same operations as those for the red-QD-dispersed liquid manufacturing step or the green-QD-dispersed liquid manufacturing step.

Subsequently, the blue-QD-dispersed liquid is used to deposit a QD-containing film 231B; that is, a blue-QD-containing film (Step S2c″: a blue-QD-containing-film depositing step). The QD-containing film 231B, which becomes the EML 23B, contains the blue QDs as the QDs 51, the ligands 52, and the photo-crosslinking agent 53.

In this embodiment, the blue-QD-dispersed liquid is applied to the photocurable-compound-containing film 221B. After that, the solvent contained in the applied blue-QD-dispersed liquid is removed. Hence, the QD-containing film 231B is deposited.

Next, the QD-containing film 231B in the blue pixel PB is irradiated with light (i.e., an active energy ray) that activates the photo-crosslinking agent 53. As a result, a blue prospective EML-forming region 23PB (the first region) of the QD-containing film 231B is irradiated with the light. Note that, here, the blue prospective EML-forming region 23PB of the QD-containing film 231B is a portion of the QD-containing film 231B, and indicates a prospective region in which the EML 43B is to be formed. Hence, the photo-crosslinking agent 53 and the ligands 52 in the blue prospective EML-forming region 23PB are crosslinked (Step S2d″: a blue QD-containing-film exposing step).

Subsequently, the photocurable-compound-containing film 221B for the blue pixel PB is irradiated with light (i.e., an active energy ray) that activates the photocurable compound. Hence, a region (i.e., the second region) included in the photocurable-compound-containing film 221B and overlapping with the blue prospective EML-forming region 23PB is irradiated with the light. Note that, here, the second region included in the photocurable-compound-containing film 221B indicates a prospective HTL-forming region included in the photocurable-compound-containing film 221B and provided for the blue pixel PB. Thus, the photocurable compound included in the second region is cured to form the photocurable resin (Step S2e″: a third photocurable-compound-containing-film exposing step, a first-functional-film third-exposing step).

As described before, the photocurable compound and the photo-crosslinking agent 53 are materials to be activated by light having the same wavelength. Hence, in this embodiment, at Steps S2d″ and S2e″, the first region and the second region are irradiated with light having the same wavelength. Thus, Steps S2d″ and S2e″ are carried out in parallel.

When the first region and the second region are exposed to light, a single photomask M3 is used. At Steps S2d″ and S2e″, for example, the photomask M3 is used. The photomask M3 includes an opening (i.e., an optical opening) so that, in plan view, the photomask M3 has: a portion corresponding to the blue prospective EML-forming region 23PB of the blue pixel PB and transparent to light; and another portion impervious to light. Thanks to such a feature, each of the first region of the QD-containing film 231B and the second region of the photocurable-compound-containing film 221B can be irradiated with the light.

Note that, in this embodiment, at Steps S2d″ and S2e″, each of the first region of the QD-containing film 231B and the second region of the photocurable-compound-containing film 221B is irradiated with UV light having a peak wavelength of 365 nm at a luminous intensity of 13 mW/cm² for 15 seconds, using the same UV emitting apparatus. Hence, the ligands 52 in the first region are crosslinked by the photo-crosslinking agent 53, and the photocurable compound in the second region is cured to form the photocurable resin.

Note that exposure conditions such as the luminous intensity at Steps S2d and S2e, Steps S2d′ and S2e′, and Steps S2d″ and S2e″ are examples. The conditions shall not be limited to the above conditions. The conditions may be set as appropriate as long as the first region in each of the QD-containing films and the second region in each of the photocurable-compound-containing films are sufficiently crosslinked and cured so as not to be dissolved by the developing solution. The conditions shall not be limited to particular conditions.

Next, the QD-containing film 231B and the photocurable-compound-containing film 221B are developed and patterned (Step S2f″: a third patterning step). At the third patterning step, a portion except the first region and the second region (i.e., a non-light-exposed region including an uncrosslinked region of the QD-containing film 231B and an uncured region of the photocurable-compound-containing film 221B) is removed.

Hence, the QD-containing film 231B is patterned to form the EML 23B and the photocurable-compound-containing film 221G is patterned to form the HTL 22B, so that an end face of the EML 23B and an end face of the HTL 22B are flush with each other. As can be seen, Steps S2b″ to S2f″ form the EML 23B and the HTL 22B to have their respective end faces flush with each other. The EML 23B overlaps the HTL 22B. For example, in plan view, the EML 23B and the HTL 22B are the same or similar (substantially the same) in shape.

Note that the developing solution shall not be limited to a particular developing solution as long as the developing solution can remove the non-light-exposed portion including the uncrosslinked region of the QD-containing film 231B and the uncured region of the photocurable-compound-containing film 221B. The developing solution may be, for example, the developing solution described before as an example.

Next, as illustrated in FIG. 6, the ETL 24 is formed (Step S2g: an ETL forming step). In this embodiment, the ETL 24 is formed (deposited) over the entire pixel region (i.e., the display region) so as to cover the HIL 21, each of the HTLs 22, and each of the EMLs 23 formed above the substrate 2.

Next, the cathode 12 is formed (Step S3″ a cathode forming step). The cathode 12 is formed over the entire pixel region (i.e., the display region) so as to cover the ETL 24.

After that, a not-shown sealing layer is formed above the substrate 2 to cover the cathode 12 (i.e., a sealing layer forming step). Note that, as described before, a not-shown functional film may be provided as necessary above the sealing layer.

Through the above steps, the display device 1 illustrated in FIG. 1 is manufactured as a light-emitting device according to this embodiment. As described before, in this embodiment, the EML 23 and the HTL 22, which serves as the first functional layer, can be patterned at once. Such a feature makes it possible to leave no residue of the EML in a region from which the EML is supposed to be removed (i.e., a region from which the QD-containing film is supposed to be removed after patterning). As a result, the display device 1 can be manufactured to have high performance.

Note that, in this embodiment, the HTL 22 is patterned as described above. Hence, as illustrated in FIG. 6, the ETL 24 and the HIL 21 are in contact with each other in a region. Thus, at the above patterning steps (Steps S2f, S2f′, and S2f″), the HTL 22 and the EML 23 are patterned to be larger in plan view than the anode 11 serving as a lower electrode.

That is, as illustrated in FIG. 6, if “a” represents a width of a lower electrode in a direction (i.e., a first direction, for example, a row direction) toward an adjacent pixel P that emits light in a different color, and “b” represents a width of, for example, an HTL 22 in the first direction, a relationship of a<b preferably holds. Note that, here, the width of the lower electrode in the first direction indicates a shortest distance (i.e., a distance in the horizontal direction) between end faces of the lower electrode in the first direction, and, more strictly, a shortest distance in the first direction between ends, of the lower electrode, in contact with the HIL 21 (i.e., between upper ends of the lower electrode). Furthermore, the width of the HTL 22 in the first direction indicates a shortest distance (i.e., a distance in the horizontal direction) between end faces of the HTL 22 in the first direction, and, specifically, a shortest distance between end faces of the HTL 22 in the first distance in plan view. More strictly, the width of the HTL 22 in the first direction indicates a shortest distance in the first direction between ends, of the HTL 22, in contact with the HIL 21 (i.e., between lower ends of the HTL 22).

As can be seen, the display device 1 according to this embodiment includes the plurality of functional layers including the HIL 21. The HIL 21, serving as the second functional layer, is provided between the anode 11 serving as a lower electrode and the HTL 22 serving as the first functional layer, and adjacent to a plurality of the anodes 11. Hence, the HIL 21 covers each of the anodes 11, and, as illustrated in FIG. 6, for example, the end faces of the EML 23 and the HTL22 in the first direction are positioned outside the end faces of the anode 11 in the first direction.

Hence, according to this embodiment, the HIL 21 and a layer provided above the EML 23 do not come into contact with each other above the anode 11. Note that, here, the layer provided above the EML 23 is such a layer as, for example, the cathode 12 serving as the upper electrode, or a functional layer provided between the EML 23 and the cathode 12. Thus, this embodiment can prevent electrical leakage at an interface between the HIL 21 and the layer provided above the EML 23.

### Second Embodiment

FIG. 7 is a cross-sectional view illustrating an example of a schematic configuration of a main feature of a display device 61 (i.e., a light-emitting device) according to this embodiment.

The display device 61 illustrated in FIG. 7 has the same configuration as the display device 1 illustrated in FIG. 1 except that the display device 61 is provided with an insulating bank BK serving as an edge cover that covers an edge (i.e., a lower electrode end) of a patterned lower electrode.

The bank BK functions as the edge cover, and also functions as a pixel separating film that divides neighboring pixels P. In this embodiment, the bank BK covers an edge of the anode 11. The bank BK is formed into, for example, a grid pattern in plan view so as to surround each of the pixels P.

The bank BK is an insulator made of, for example, an insulating organic material. The insulating organic material preferably contains a photosensitive resin. Examples of the insulating organic material include a polyimide resin and an acrylic resin.

A method for manufacturing the display device 61 according to this embodiment includes the same steps as those of the method for manufacturing the display device 1 according to the first embodiment, except that the former method includes a bank forming step of forming the bank BK after Step S1 and before Step S2. Note that the bank BK is formed, for example, as follows. A photosensitive resin is applied to the substrate 2 and the anode 11. After that, the applied photosensitive resin is patterned by photolithography to form the bank BK into a desired shape.

Similar to the display device 1 illustrated in FIG. 1, the display device 61 according to this embodiment includes the HIL 21 provided between the anode 11 and the HTL 22, and adjacent to the plurality of anodes 11. The HIL 21 serves as the second functional layer. Hence, the HIL 21 covers each of the anodes 11, and, as illustrated in FIG. 7, for example, the end faces of the EML 23 and the HTL 22 in the first direction are positioned outside the end faces of the anode 11 in the first direction. Such a feature can prevent electrical leakage at an interface between the HIL 21 and a layer provided above the EML 23.

Additionally, in this embodiment, the bank BK is provided to an edge of the anode 11 as described above. Hence, as illustrated in FIG. 7, a width of a region, in the first direction, in which the anode 11 is in direct contact with the HIL 21 is narrower than a width between the end faces of the anode 11 in the first direction. Hence, the width of the region, in the first direction, in which the anode 11 is in direct contact with the HIL 21 is narrower than a width between the end faces of the EML 23 in the first direction and a width between the end faces of the HTL 22 in the first direction. That is, as illustrated in FIG. 7, if “c” represents a width of the region, in the first direction, in which the anode 11 and the HIL 21 are in direct contact with each other, “a” represents a width of the lower electrode in the first direction as described above, and “b” represents a width of, for example, the HTL 22 in the first direction, a relationship of c<a<b holds. Hence, the end faces of the EML 23 and the HTL 22 in the first direction are positioned outside the end portions of the region, in the first direction, in which the anode 11 is in direct contact with the HIL 21.

Note that “a” and “b” have been previously described in the first embodiment. Furthermore, “c” represents the width of the region, in the first direction, in which the anode 11 and the HIL 21 are in direct contact. The width indicates a shortest distance (i.e., a distance in the horizontal direction), in the first direction, across the region in which the anode 11 and the HIL 21 are in direct contact with each other. More specifically, the “c” represents a shortest distance in the first direction between ends, of the anode 11 serving as the lower electrode, in contact with the HIL 21 (i.e., a shortest distance in the first direction between lower ends, of the bank BK, on the anode 11).

As can be seen, this embodiment can set a distance longer in plan view between: an end at which the HILL 21 serving as the second functional layer and the anode 11 serving as the lower electrode are in contact with each other; and end faces of the HTL 22 and the EML 23 than the first embodiment can. Thus, the second embodiment can set the distance longer in plan view between: the end at which the HIL 21 serving as the second functional layer and the anode 11 serving as the lower electrode are in contact with each other; and a region in which the HIL 21 and the ETL 24 are in contact with each other than the first embodiment can. Hence, this embodiment can prevent more reliably electrical leakage at an interface between the HIL 21 and a layer provided above the EML 23.

Furthermore, in the display device 61, in plan view, a shortest distance between: an end of a region in which the anode 11 serving as the lower electrode and the HILL 21 are in direct contact with each other; and end faces of the EML23 and the HTL22 is preferably longer than a sum of thicknesses of the functional layers between the anode 11 and the cathode 12. That is, if “d” represents the sum of the thicknesses of the functional layers between the anode 11 and the cathode 12 (i.e., the sum of the thicknesses from HIL 21 to the ETL 24 in the example illustrated in FIG. 7), a relationship of (b−c)/2>d preferably holds.

In such a case, the second embodiment can set the distance even longer in plan view between: the end at which the HIL 21 serving as the second functional layer and the anode 11 serving as the lower electrode are in contact with each other; and a region in which the HIL 21 and the ETL 24 are in contact with each other than the first embodiment can. Such a feature can more reliably prevent electrical leakage at an interface between the HIL 21 and a layer provided above the EML 23.

### Third Embodiment

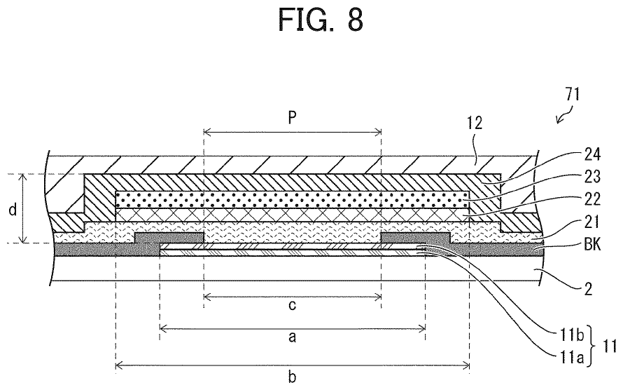

FIG. 8 is a cross-sectional view illustrating an example of a schematic configuration of a main feature of a display device 71 (i.e., a light-emitting device) according to this embodiment.

The display device 71 according to this embodiment is the same as the display devices according to the first and second embodiments except for the points below. Note that exemplified below will be a case where, as illustrated in FIG. 8, the display device 71 includes the bank BK. Hence, described below will be a difference from the display device 61 according to the second embodiment. However, the difference of the display device 71 according to this embodiment shall not be limited to a particular difference. The display device 71 may be different from the display device 1 as to the points below.

The display device 71 according to this embodiment is a top-emission display device, and the upper electrode is a light-transparent electrode. The lower electrode also serves as a reflector, and includes: a reflective electrode; and a light-transparent electrode provided above the reflective electrode.

According to this embodiment, the light-transparent electrode is provided above the reflective electrode. Such a feature can protect the reflective electrode with the light-transparent electrode. Hence, this embodiment can provide a top-emission light-emitting device in which a reflective electrode is protected with a light-transparent electrode.

Note that this embodiment exemplifies a case where the anode 11 serving as a lower electrode has a multilayer structure including: a reflective electrode 11a; and a light-transparent electrode 11b provided above the reflective electrode 11a. The reflective electrode 11a is an Ag electrode having a thickness of 100 nm. The light-transparent electrode 11b is an ITO electrode having a thickness of 10 nm. Furthermore, the cathode 12 serving as an upper electrode is an ITO electrode having a thickness of 100 nm. Note that this embodiment shall not be limited to the above case. In order to protect the reflective electrode, the light-transparent electrode provided in contact with the reflective electrode may have a thickness of, for example, several nanometers or more and two hundred nanometers or less.

Moreover, although not shown, the lower electrodes of the light-emitting elements EL in the pixels P may have different thicknesses for each color of light to be emitted so as to maximize efficiency in releasing light from each of the pixels P. Specifically, the light-transparent electrodes in the lower electrodes may have different thicknesses, depending on colors of light to be emitted from the pixels P.

As can be seen, the light-transparent electrodes in the lower electrodes may have different thicknesses, depending on colors of light to be emitted from the pixels P. Such a feature makes it possible to optimize a thickness between the reflective electrode of a lower electrode and the upper electrode, and amplify emission intensity of a specific wavelength. Furthermore, when the light-transparent electrodes in the lower electrodes have different thicknesses, a thickness between the reflective electrode of a lower electrode and the upper electrode can be optimized regardless of a carrier balance in the functional layers.

### Fourth Embodiment

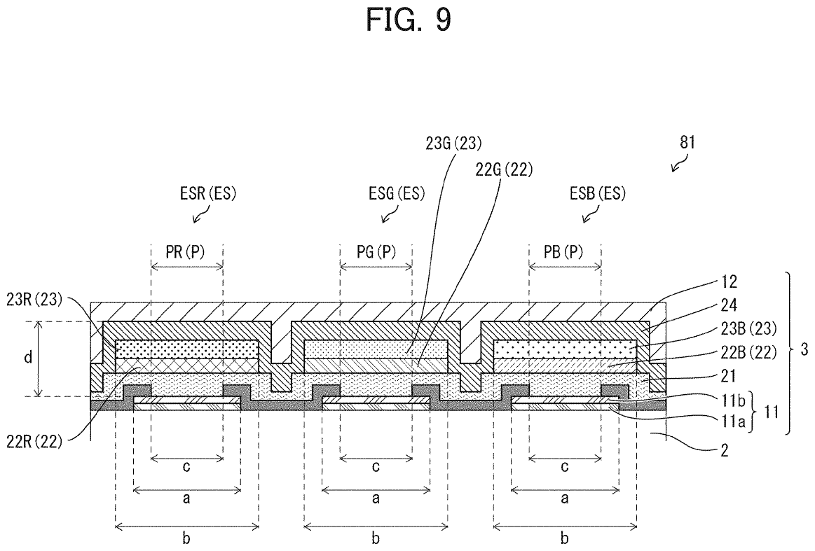

FIG. 9 is a cross-sectional view illustrating an example of a schematic configuration of a main feature of a display device 81 (i.e., a light-emitting device) according to this embodiment.

The display device 81 according to this embodiment is the same as the display devices according to the first to third embodiments except for the points below. Note that described below will be a difference from the display device 71 according to the third embodiment. However, the difference of the display device 81 according to this embodiment shall not be limited to a particular difference. The display device 81 may be different from either the display device 1 or the display device 61 as to the points below.

In the display device 81 according to this embodiment, as illustrated in FIG. 9, the HTL 22 serving as a first functional layer is thickest in the red pixel PR (i.e., a red light-emitting region) and thinnest in the blue pixel PB (i.e., a blue light-emitting region). Such a feature makes it possible to improve efficiency in releasing light when the display device 81 includes the red pixel PR, the green pixel PG, and the blue pixel PB as described above.

Note that this embodiment exemplifies a case where the anode 11 serving as a lower electrode has a multilayer structure including: an Ag electrode having a thickness of 100 nm; and an ITO electrode having a thickness of 10 nm and stacked on the Ag electrode. On the anode 11, the HIL 21 having a thickness of 30 nm is stacked. Furthermore, the HTL 22R has a thickness of 100 nm, the HTL 22G has a thickness of 40 nm, and the HTL 22B has a thickness of 20 nm. Each of the EML 23R, the EML 23G, and the EML 23B has a thickness of 30 nm. Moreover, the ETL 24 has a thickness of 60 nm. As can be seen, the HTLs 22 are thicker in the order of the HTL 22R, the HTL 22G, and the HTL 22B. Such a feature can maximize efficiency in releasing light.

### First Modification

The first to fourth embodiments exemplify a case where the display devices have a known structure in which the anode 11 is a lower electrode and the cathode 12 is an upper electrode. However, the display devices according to the present disclosure may have an inverted structure in which the cathode 12 is a lower electrode, and the anode 11 is an upper electrode. Hence, each of the above display devices may have a first functional layer serving as, for example, the ETL 24 and a second functional layer serving as, for example, the EIL. In this case, also, the EML 23 includes: the QDs 51; the ligands 52; and the photo-crosslinking agent 53, and the ETL 24 contains a photocurable resin. Such a feature can provide a light-emitting device having no residue of a light-emitting photocurable resin left in a region where the light-emitting layer is supposed to be patterned and removed, thereby presenting excellent performance and color purity. The feature can also provide a method for manufacturing the light-emitting device.

### Second Modification

Furthermore, the first functional layer may be a functional layer other than the charge transport layer, and may be, for example, either an EBL or an HBL.

The EBL, which blocks transportation of the electrons, may be provided between the anode 11 and the EML 23 in contact with, for example, the EML 23. The EBL can adjust the balance of carriers (i.e., the holes and the electrons) to be supplied to the EML 23. As a material of the EBL, for example, an organic insulating material can be used. Furthermore, the material of the EBL may also be a hole transporting material.

The HBL, which blocks transportation of the holes, may be provided between the cathode 12 and the EML 23 in contact with, for example, the EML 23. The HBL can also adjust the balance of carriers to be supplied to the EML 23. As a material of the HBL, for example, an organic insulating material can be used. Furthermore, the material of the HBL may also be an electron transporting material.

### Third Modification

Moreover, the first to fourth embodiments exemplify a case where the light-emitting devices according to the present disclosure are full-color display device. However, the above light-emitting devices shall not be limited to such case. The light-emitting devices may be, for example, display devices such as a traffic light that emits light in a signal color.

When a design pattern is presented by a display device such as a traffic signal, if the residue of the light-emitting layer is left in a region from which the EML is supposed to be removed after patterning, an unintended region would emit light, which might affect the design pattern. Hence, the technique according to the present disclosure is also applied to such a display device that emits light in a single color. The technique makes it possible to provide a light-emitting device having no residue of the EML left in a region where the EML is supposed to be patterned and removed, thereby presenting excellent performance and color purity. The technique can also provide a method for manufacturing the light-emitting device.

### Fourth Modification

In addition, the light-emitting devices according to the present disclosure shall not be limited to display devices. The light-emitting devices may be, for example, light-emitting devices such as light-emitting elements. For example, if a region other than the light-emitting region is provided on the substrate; that is, if the light-emitting region and a terminal unit are provided on the substrate, the EML needs to be removed from the region other than the light-emitting region. The technique according to the present disclosure is also applied to such a case. The technique makes it possible to provide a light-emitting device having no residue of the EML left in a region where the light-emitting layer is supposed to be patterned and removed, thereby presenting excellent performance and color purity. The technique can also provide a method for manufacturing the light-emitting device.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A light-emitting device, comprising
at least one light-emitting region,
wherein the at least one light-emitting region includes:
a lower electrode in plan view;
an upper electrode provided across from at least one lower electrode including the lower electrode; and
a plurality of functional layers stacked on top of another between the lower electrode and the upper electrode,
the plurality of functional layers include at least:
a light-emitting layer provided between the lower electrode and the upper electrode; and
a first functional layer provided between the lower electrode and the light-emitting layer, and adjacent to the light-emitting layer,
the light-emitting layer contains quantum dots, ligands, and a photo-crosslinking agent,
the first functional layer contains a photocurable resin, and
an end face of the light-emitting layer and an end face of the first functional layer are flush with each other.

2. The light-emitting device according to claim 1,
wherein the at least one light-emitting region includes a plurality of light-emitting regions,
the plurality of light-emitting regions include:
a plurality of lower electrodes including the lower electrode in plan view; and
the plurality of functional layers provided between each of a plurality of the lower electrodes and the upper electrode.

3. The light-emitting device according to claim 2,
wherein, for each of the plurality of light-emitting regions, the light-emitting layer has a different peak emission wavelength.

4. The light-emitting device according to claim 3,
wherein the plurality of light-emitting regions include: a red light-emitting region configured to emit a red light; a green light-emitting region configured to emit a green light; and a blue light-emitting region configured to emit a blue light, and
the first functional layer is thickest in the red light-emitting region and thinnest in the blue light-emitting region.

5. The light-emitting device according to claim 1,
wherein the first functional layer is insoluble in an organic solvent containing 80 vol % or more of a solvent having both a polarity term and a hydrogen bonding term of 0 among Hansen solubility parameter values.

6. The light-emitting device according to claim 1,
wherein the ligands are nonpolar ligands.

7. The light-emitting device according to claim 1,
wherein the photo-crosslinking agent contains polyazide containing two or more azide groups or nitrene groups.

8. The light-emitting device according to claim 7,
wherein the polyazide contain at least one selected from the group consisting of compounds represented by Formulae (1) to (10) below: 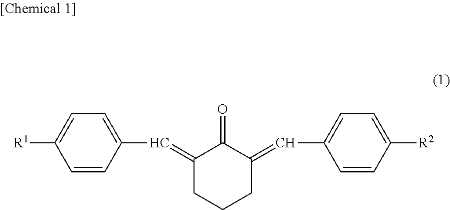
wherein each of R¹ and R² independently represents an azide group or a nitrene group, 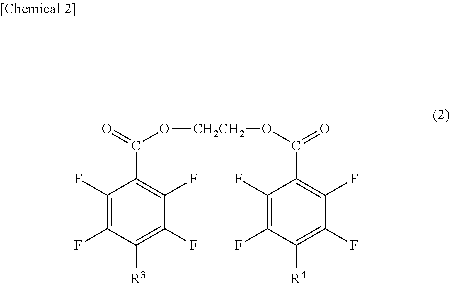
wherein each of R³ and R⁴ independently represents an azide group or a nitrene group, 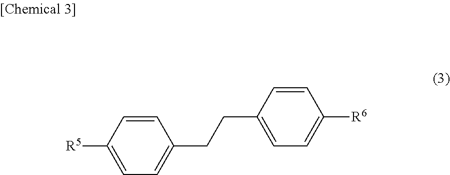
wherein each of R⁵ and R⁶ independently represents an azide group or a nitrene group, 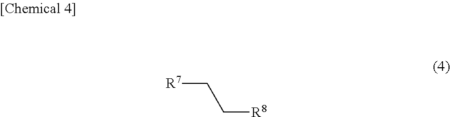
wherein each of R⁷ and R⁸ independently represents an azide group or a nitrene group, 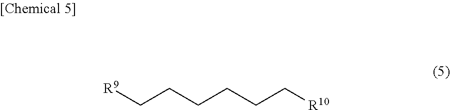
wherein each of R⁹ and R¹⁰ independently represents an azide group or a nitrene group, 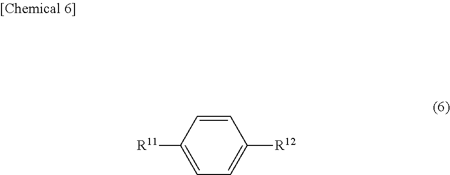
wherein each of R¹¹ and R¹² independently represents an azide group or a nitrene group, 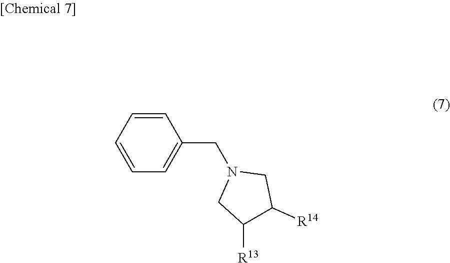
wherein each of R¹³ and R¹⁴ independently represents an azide group or a nitrene group, 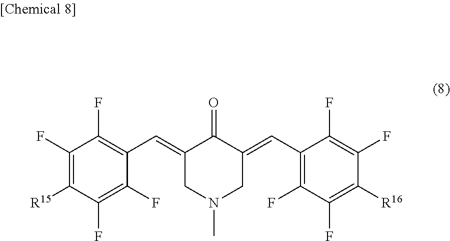
wherein each of R¹⁵ and R¹⁶ independently represents an azide group or a nitrene group, 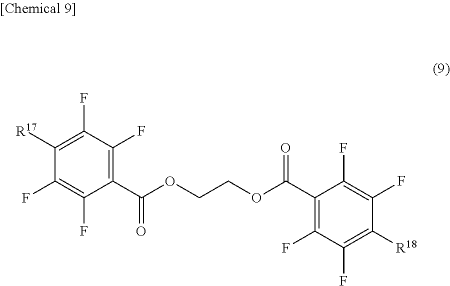
wherein each of R¹⁷ and R¹⁸ independently represents an azide group or a nitrene group, and 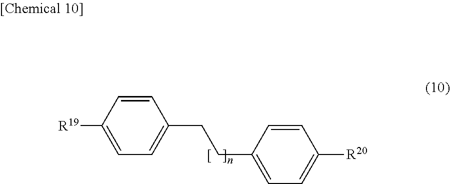
wherein each of R¹⁹ and R²⁰ independently represents an azide group or a nitrene group, and n represents either 0 or 1.

9. The light-emitting device according to claim 1,
wherein the photo-crosslinking agent and the photocurable resin are formed of a material to be activated by light having an equal wavelength.

10. The light-emitting device according to claim 9,
wherein the light is UV light.

11. The light-emitting device according to claim 1,
wherein the first functional layer is a charge transport layer.

12. The light-emitting device according to claim 11,
wherein the charge transport layer is a hole transport layer.

13. The light-emitting device according to claim 1,
wherein the first functional layer further contains a photopolymerization initiator.

14. The light-emitting device according to claim 1,
wherein the plurality of functional layers include a second functional layer provided between the lower electrode and the first functional layer, and adjacent to a plurality of lower electrodes including the lower electrode,
the second functional layer covers the lower electrode, and
the end face of the light-emitting layer and the end face of the first functional layer are positioned outside an end face of the lower electrode.

15. The light-emitting device according to claim 14, further comprising
an edge cover covering an edge of the lower electrode,
wherein, in plan view, a shortest distance between: an end of a region in which the lower electrode and the second functional layer are in direct contact with each other; and the end faces of light-emitting layer and the first functional layer is longer than a sum of thicknesses of the plurality of functional layers between the lower electrode and the upper electrode.

16. The light-emitting device according to claim 1,
wherein the upper electrode is a light-transparent electrode, and
the lower electrode includes: a reflective electrode; and a light-transparent electrode provided above the reflective electrode.

17. A method for manufacturing a light-emitting device including at least one light-emitting region, the method comprising:
a lower electrode forming step of forming, in plan view, a lower electrode in the at least one light-emitting region;
a functional layer forming step of forming a plurality of functional layers above the lower electrode in the at least one light-emitting region; and
an upper electrode forming step of forming an upper electrode, across from at least one lower electrode including the lower electrode, above the plurality of functional layers in the at least one light-emitting region,
wherein the functional layer forming step includes:
a first-functional-film depositing step of depositing a first functional film containing a photocurable compound;
a quantum-dot-containing-film depositing step of depositing a quantum-dot-containing film above, and adjacent to, the first functional film, the quantum-dot-containing film containing the quantum dots, ligands, and photo-crosslinking agent;
a quantum-dot-containing-film exposing step of exposing a first region, which is a portion of the quantum-dot-containing film, with light to activate the photo-crosslinking agent, and crosslinking the photo-crosslinking agent and the ligands in the first region;
a first-functional-film exposing step of exposing a second region, which is included in the first functional film and overlaps with the first region, with light to activate the photocurable compound, and curing the photocurable compound in the second region to form a photocurable resin; and
a patterning step of developing to pattern the quantum-dot-containing film and the first functional film, so that the quantum-dot-containing film is patterned to form a light-emitting layer, and the first functional film is patterned to form a first functional layer having an end face flush with an end face of the light-emitting layer.

18. The method for manufacturing the light-emitting device according to claim 17,
wherein the photocurable compound and the photo-crosslinking agent are materials to be activated by light having an equal wavelength; and
at the quantum-dot-containing-film exposing step and at the first-functional-film exposing step, the first region and the second region are irradiated with light having the equal wavelength, so that the quantum-dot-containing-film exposing step and the first-functional-film exposing step are carried out in parallel.
